(19) United States
(12) Patent Application Publication
(10) Pub. No.: US 2025/0393328 A1
(43) Pub. Date: Dec. 25, 2025

(54) SENSOR FAN-OUT PACKAGING

(71) Applicant: SEMICONDUCTOR COMPONENTS INDUSTRIES, LLC, Scottsdale, AZ (US)

(72) Inventors: Swarnal BORTHAKUR, Boise, ID (US); Xunzhi LI, Boise, ID (US); Robert Michael GRAVELLE, JR., Boise, ID (US)

(73) Assignee: SEMICONDUCTOR COMPONENTS INDUSTRIES, LLC, Scottsdale, AZ (US)

(21) Appl. No.: 18/747,936

(22) Filed: Jun. 19, 2024

(51) Int. Cl. H01L 27/146; G01J 1/04; G01J 1/44; G01S 7/03

(52) U.S. Cl. CPC H10F 39/811; G01J 1/0407; G01J 1/44; G01S 7/032; H10F 39/011; H10F 39/804; G01J 2001/448

(57) ABSTRACT

A sensor package may include a radiation transmitting substrate. A sensor package may include a sensor module coupled to the radiation transmitting substrate via a material that positions the radiation transmitting substrate away from an active region of the radiation transmitting substrate. The sensor module includes an integrated circuit embedded into the sensor module. The sensor module includes a fan-out structure including a first end portion and a second end portion. The first end portion is coupled to the integrated circuit. The second end portion is coupled to a conductive component. A sensor package may include a substrate coupled to the sensor module.

### BACKGROUND

Some conventional sensor packages may have package structures that introduce flare when a package or die size is reduced.

### SUMMARY

In some aspects, the techniques described herein relate to a sensor package including: a radiation transmitting substrate; and a sensor module coupled to the radiation transmitting substrate via a material (e.g., a dam member, adhesive material) that positions the radiation transmitting substrate away from an active region of the radiation transmitting substrate, the sensor module including an integrated circuit embedded into the sensor module, the sensor module including a fan-out structure including a first end portion and a second end portion, the first end portion being coupled to the integrated circuit, the second end portion being coupled to a conductive component; and a substrate coupled to the sensor module.

In some aspects, the techniques described herein relate to a sensor module including: an active region; a sensor layer; an integrated circuit layer; and a fan-out structure including a first end portion and a second end portion, the first end portion being coupled to a contact terminal defined by the integrated circuit layer, the second end portion configured to be coupled to a conductive component.

In some aspects, the techniques described herein relate to a method for manufacturing a sensor module, the method including: receiving a sensor substrate assembly, the sensor substrate assembly including an active region, a sensor layer, and an integrated circuit layer, the integrated circuit layer defining a contact terminal, the sensor substrate assembly including a hole that extends through the sensor layer to the contact terminal; coupling a portion of the sensor substrate assembly to a wafer substrate; applying a molding material to the wafer substrate; and forming a fan-out structure by depositing conductive material to the hole and the molding material.

The details of one or more implementations are set forth in the accompanying drawings and the description below. Other features will be apparent from the description and drawings, and from the claims.

### BRIEF DESCRIPTION OF THE DRAWINGS

FIGS. 1A and 1B illustrate examples of a sensor module according to various aspects.

FIGS. 2A and 2B illustrate an example of a sensor package with a sensor module according to an aspect.

FIG. 3 illustrates an example of a sensor module according to an aspect.

FIG. 4 illustrates an example of a sensor module according to another aspect.

FIG. 5 illustrates an example of a sensor module according to another aspect.

FIGS. 6A and 6B illustrate an example of a sensor package with a sensor module according to an aspect.

FIGS. 7A to 7G illustrate a process of constructing a sensor module according to an aspect.

FIGS. 8A to 8D illustrate a process of constructing a sensor module according to another aspect.

FIGS. 9A to 9C illustrate a process of constructing a sensor module according to another aspect.

FIGS. 10A to 10D illustrate a process of constructing a sensor module according to another aspect.

FIGS. 11A to 11I illustrate a process of constructing a sensor package according to another aspect.

FIG. 12 illustrates a flowchart depicting example operations of manufacturing a sensor module according to an aspect.

### DETAILED DESCRIPTION

The present disclosure relates to a sensor package with a fan-out structure that may reduce the size of the sensor package while reducing (or eliminating) package related flare (e.g., flare from a vertical edge of glass, flare from a glass attach adhesive, and/or flare from a bond wire or a conductive pad, etc.). The sensor package includes a substrate, and a sensor module coupled to the substrate, where the sensor module is configured to detect energy photons or electromagnetic radiation such as radar or light signals. In some examples, the sensor module is an image sensor module configured to capture image data. The sensor module includes an application-specific integrated circuit embedded into the sensor module. The fan-out structure includes a first end portion coupled to an application-specific integrated circuit.

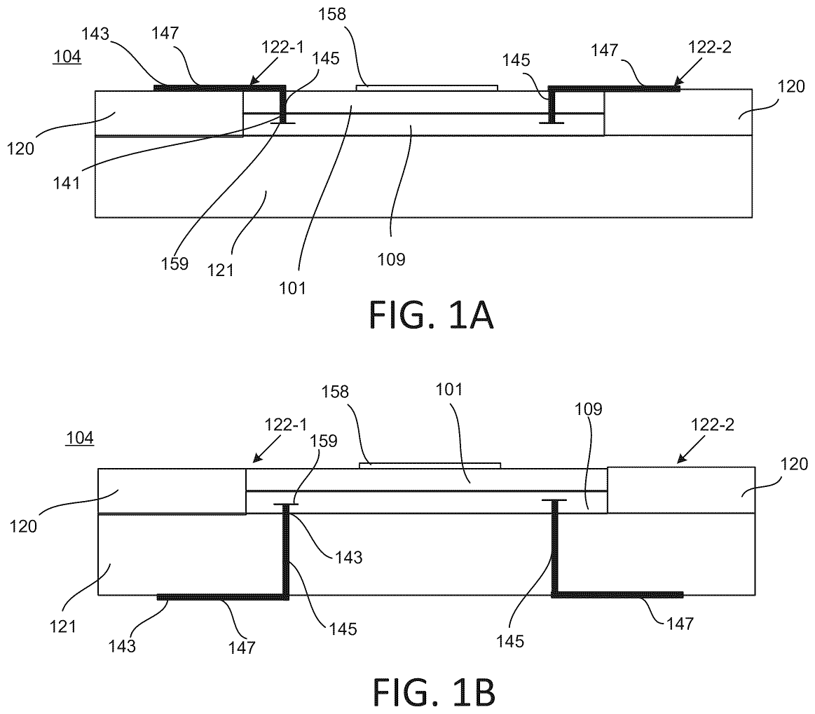

FIG. 1A illustrates a sensor module 104 for a sensor package according to an aspect. The sensor module 104 is integrated with an application-specific circuit, and includes fan-out structures 122-1, 122-2. The fan-out structures may be referred to as redistribution layers. The image sensor module 104 of FIG. 1A depicts the fan-out structures on the front-side of the image sensor module 104. The sensor module 104 is configured to detect energy photons or electromagnetic radiation such as radar or light signals. In some examples, the sensor module 104 is an electromagnetic radiation detector. In some examples, the sensor module 104 is a photon detector. In some examples, the sensor module 104 is an image sensor module configured to capture image data. In some examples, the sensor module 104 is used for image sensing. In some examples, the sensor module 104 is used for autonomous driving. In some examples, the sensor module 104 is used for object detection (e.g., industrial object detection).

In some examples, the image sensor module 104 may be, or referred to as, a sensor die (e.g., an image sensor die) or a sensor device (e.g., an image sensor device). In some examples, the sensor module 104 generates image data from light at an active region 158. However, the sensor module 104 may detect energy photons or electromagnetic radiation such as radar, or light signals. The active region 158 may have or correspond with, an array of elements (e.g., pixel elements) configured to convert electromagnetic radiation (e.g., light, radar, etc.) or energy photons to electrical signals. The sensor module 104 includes one or more sensor layers 101. In some examples, the sensor layers 101 are image sensor layers. The sensor module 104 may include multiple image layers 101 that are stacked on top of each other.

The image sensor module 104 is integrated with an application-specific integrated circuit. For example, the sensor module 104 includes an application-specific integrated circuit that is integrated, embedded, and/or included within a structure of the sensor module 104. The application-specific integrated circuit includes one or more integrated circuit layers 109 that are disposed below the sensor layer 101. In some examples, the application-specific integrated circuit includes multiple integrated circuit layers 109 that are stacked on top of each other.

The sensor module 104 includes a wafer substrate 121 coupled to the backside of the integrated circuit layer(s) 109. In some examples, the wafer substrate 121 is a silicon substrate or organic or ceramic substrate. The sensor module 104 includes a molding 120. The molding 120 may be disposed on the wafer substrate 121 around the sensor layer(s) 101 and the integrated circuit layer(s) 109.

The sensor module 104 includes one or more fan-out structures 122-1, 122-2 that connect the application-specific integrated circuit to a conductive component (not shown in FIGS. 1A or 1B) (e.g., a bond wire, or a conductive ball member). The fan-out structure 122-1 includes a first end portion 141 that contacts a contact terminal 159 defined by the integrated circuit layer 109 and a second end portion 143 disposed on the molding 120.

The fan-out structure 122-1 includes one or more conductive portions (e.g., conductive traces or lines). The fan-out structure 122-1 includes a conductive portion 145 that extends through (e.g., entirely through) the sensor layer 101 of the sensor module 104. The fan-out structure 122-1 includes a conductive portion 147 that extends along (and contacts) the top surface of a portion of the sensor layer 101. The conductive portion 147 extends along (and contacts) the molding 120. The conductive portion 147 defines the second end portion 143. The sensor module 104 includes a fan-out structure 122-2 on the other side of the active region 158. The fan-out structure 122-2 may have the same structure as the fan-out structure 122-1, and, therefore, may include any of the details discussed with reference to the fan-out structure 122-1.

FIG. 1B illustrates a sensor module 104 for a sensor package according to another aspect. The sensor module 104 is integrated with an application-specific circuit, and includes fan-out structures 122-1, 122-2. The fan-out structures may be referred to as redistribution layers. The sensor module 104 of FIG. 1B depicts the fan-out structures on the back-side of the sensor module 104.

The fan-out structure 122-1 includes a first end portion 141 that contacts a contact terminal 159 defined by the integrated circuit layer 109 and a second end portion 143 disposed on a surface of the wafer substrate 121. The fan-out structure 122-1 includes one or more conductive portions (e.g., conductive traces or lines). The fan-out structure 122-1 includes a conductive portion 145 that extends through a portion of the integrated circuit layer 109 and through (e.g., entirely through) the wafer substrate 121. The fan-out structure 122-1 includes a conductive portion 147 that extends along (and contacts) the bottom surface of a portion of the wafer substrate 121.

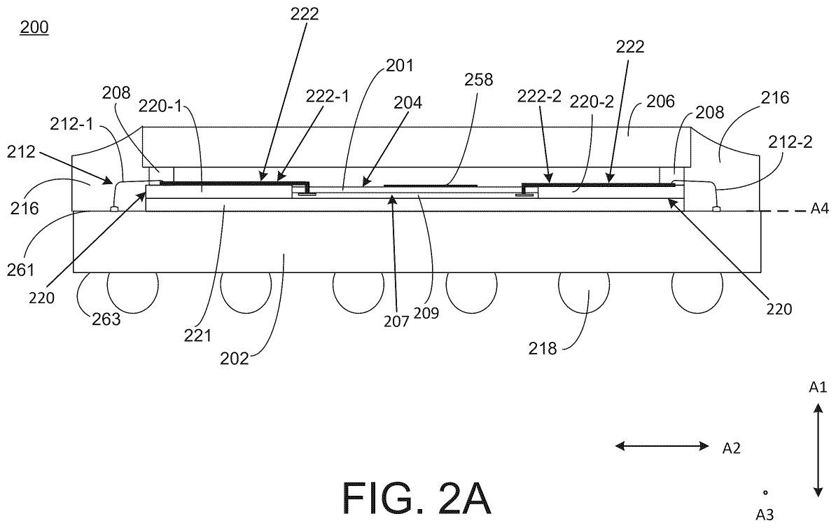

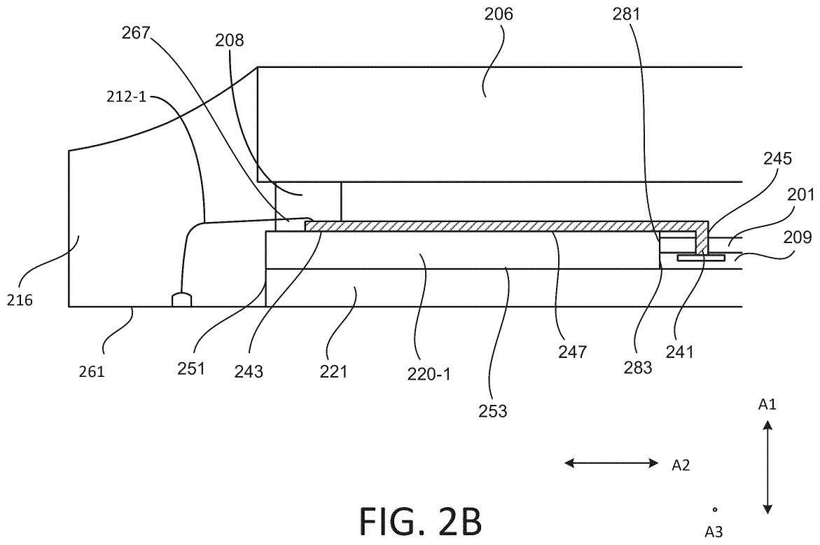

FIGS. 2A and 2B illustrate a sensor package 200 according to an aspect. The sensor package 200 includes a substrate 202, a sensor module 204 coupled to the substrate 202, and a radiation transmitting substrate 206 coupled to the sensor module 204 via a material 208. The material 208 may be a dam member that positions the radiation transmitting substrate 206 away from an active region 256. The sensor package 200 includes a plurality of conductive components 218 coupled to the substrate 202.

In some examples, the image sensor module 204 may be, or referred to as, a sensor die (e.g., an image sensor die) or a sensor device (e.g., an image sensor device). In some examples, the sensor module 204 generates image data from light at an active region 258. However, the sensor module 204 may detect energy photons or electromagnetic radiation such as radar, or light signals. The sensor module 204 includes one or more sensor layers 201 and an active region 258 configured to receive electromagnetic radiation (e.g., radar, light, or photos) through the radiation transmitting substrate 206. The active region 258 may have or correspond with, an array of pixel elements configured to convert electromagnetic radiation (e.g., light) to electrical signals.

The sensor module 204 may include multiple sensor layers 201 that are stacked on top of each other. The sensor layer(s) 201 may have a length in a direction A2, a width in a direction A3, and a thickness in a direction A1. A first surface 261 of the substrate 202 is disposed in a plane A4. A direction A1 is aligned perpendicular to the plane A4, and a direction A2 is perpendicular to the direction A1. A direction A3 is aligned parallel to the plane A4 and is orthogonal to directions A1 and A2.

The sensor module 204 is integrated with an application-specific integrated circuit 207. For example, the sensor module 204 includes an application-specific integrated circuit 207 that is integrated, embedded, and/or included within a structure of the sensor module 204. The application-specific integrated circuit 207 includes one or more integrated circuit layers 209 that are disposed below the sensor layer 201 in the direction A1. In some examples, the application-specific integrated circuit 207 includes multiple integrated circuit layers 209 that are stacked on top of each other. The sensor layer 201 may be stacked on top of the integrated circuit layer 209 in the direction A1. The application-specific integrated circuit 207 (e.g., the integrated circuit layer(s) 209) may have a length in a direction A2, a width in a direction A3, and a thickness in a direction A1. In some examples, the length and/or the width of the integrated circuit layer(s) 209 is/are the same as the length and/or the width of the sensor layer(s) 201.

The sensor module 204 includes a wafer substrate 221 coupled to the substrate 202 and the backside of the integrated circuit layers 209. The wafer substrate 221 is coupled to the application-specific integrated circuit 207 (e.g., the integrated circuit layer 209). In some examples, the wafer substrate 221 is a silicon substrate. In some examples, the wafer substrate 221 has a length in the direction A2 and/or a width in the direction A3 that is/are greater than the length and/or the width of the sensor layer 201 and/or the length and/or the width of the integrated circuit layer 209.

The sensor module 204 includes a molding 220. Referring to FIGS. 2A and 2B, the molding 220 is disposed on and contacts a surface 253 (e.g., a top surface) of the wafer substrate 221. The molding 220 may be disposed on the wafer substrate 221 around the sensor layer(s) 201 and the integrated circuit layer(s) 209. For example, the molding 220 includes a molding portion 220-1 that contacts the surface 253 on a first portion of the wafer substrate 221. The molding portion 220-1 contacts an edge 281 of the sensor layer 201 and contacts an edge 283 of the integrated circuit layer 209. The molding portion 220-1 extends in the direction A2 to a location that aligns (e.g., corresponds to) with an edge 251 of the wafer substrate 221.

The molding 220 includes a molding portion 220-2 disposed on another portion of the wafer substrate 221. The molding portion 220-2 may have the same structure as the molding portion 220-1, and, therefore, may include any details discussed with reference to the molding portion 220-1. The molding portion 220-2 contacts the surface 253 of a second portion of the wafer substrate 221. The molding portion 220-2 contacts the other edges of the sensor layer 201 and the integrated circuit layer 209. The molding portion 220-2 extends in a direction A2 to a location that aligns with the other edge of the wafer substrate 221.

The sensor module 204 includes one or more fan-out structures 222 that connect the application-specific integrated circuit 207 to each of a bond wire 212-1 and a bond wire 212-2 at a bond-wire connection point. The bond-wire connection point is located away from the active region 258 of the sensor module 204. For example, a fan-out structure 222 include a portion (e.g., a conductive portion) that is connected to the application-specific integrated circuit 207, a portion that extends through the sensor layer(s) 201, a portion that extends along (and contacts) a molding portion (e.g., molding portion 220-1 or molding portion 220-2) to a location where the radiation transmitting substrate 206 is coupled to the sensor module 204 via the material 208 (e.g., a dam member, an adhesive material).

The sensor module 204 may include a fan-out structure 222-1 and a fan-out structure 222-2. The fan-out structure 222-1 may extend in a first direction in the direction A2, and the fan-out structure 222-2 may extend in a second direction in the direction A2, where the first and second directions are opposite directions.

As shown in FIG. 2B, the fan-out structure 222-1 includes a first end portion 241 that contacts the application-specific integrated circuit 207 (e.g., a portion of the integrated circuit layer 209) and a second end portion 243 disposed on the molding portion 220-1 at a first location that aligns with the material 208 and/or away from the active region 258. The second end portion 243 is connected to the bond wire 212-1. In some examples, the second end portion 243 of the fan-out structure 222-1 is encapsulated by the material 208 that bonds the sensor module 204 to the radiation transmitting substrate 206. For example, the second end portion 243 is connected to the bond wire 212-1, and the material 208 contacts the bond wire connection between the second end portion 243 and the bond wire 212-1.

The fan-out structure 222-1 includes one or more conductive portions (e.g., conductive traces or lines). The fan-out structure 222-1 includes a conductive portion 245 that extends through (e.g., entirely through) the sensor layer 201 of the sensor module 204 in the direction A1. The fan-out structure 222-1 includes a conductive portion 247 that extends along (and contacts) the top surface of a portion of the sensor layer 201 in the direction A2. The conductive portion 247 extends along (and contacts) the molding portion 220-1 in the direction A2. The conductive portion 247 defines the second end portion 243. The sensor module 204 includes a fan-out structure 222-2 on the other side of the active region 258. The fan-out structure 222-2 may have the same structure as the fan-out structure 222-1, and, therefore, may include any of the details discussed with reference to the fan-out structure 222-1.

The sensor package 200 includes a substrate 202 coupled to the sensor module 204. The substrate 202 is coupled to the wafer substrate 221. In some examples, the sensor module 204 is coupled to the substrate 202 using one or more bonding materials (e.g., an adhesive layer, die attach film, polymer-based material, an epoxy resin, etc.) in order to physically couple the sensor module 204 to the substrate 202. In some examples, the sensor module 204 is coupled to the substrate 202 by surface mount technology (SMT) (e.g., interconnection by solder joint or sintering joint).

The substrate 202 may have a length in the direction A2, a width in a direction A3, and a thickness in a direction A1. The substrate 202 includes a first surface 261 and a second surface 263. In some examples, the length of the substrate 202 is greater than the length of the wafer substrate 221 in the direction A2. The substrate 202 includes a dielectric layer. The dielectric layer includes an insulating material. In some examples, the dielectric layer includes a ceramic material. In some examples, the substrate 202 includes a single dielectric layer. In some examples, the substrate 202 includes multiple dielectric layers. In some examples, the substrate 202 includes a printed circuit board (PCB) substrate (e.g., a single layer of PCB or multiple layers of PCB). In some examples, the substrate 202 includes one or more conductive layer portions (e.g., electrical traces) disposed on the first surface 261 of the substrate 202, and/or one or more conductive layer portions (e.g., electrical traces) disposed on the second surface 263 of the substrate 202. In some examples, the electrical traces may be configured to and/or used to transmit signals to and/or from devices (e.g., electronic devices included in a semiconductor region (e.g., epitaxial layer and/or semiconductor substrate)) connected to the electrical traces. In some examples, the electrical traces can include conductive traces (e.g., metallic traces) such as copper traces, aluminum traces, and/or so forth.

The sensor package 200 includes one or more bond wires 212 connected to the fan-out structure(s) 222 and to the substrate 202. In some examples, the bond wires 212 are connected to the fan-out structure(s) 222 of the sensor module 204 and the substrate 202 in order to communicatively couple the sensor module 204 and the application-specific integrated circuit 207 to the substrate 202. The bond wires 212 may include conductive (e.g., metal) wires such as aluminum, copper, or gold, or any combination thereof, for example.

The sensor package 200 includes a bond wire 212-1. The bond wire 212-1 includes a first end portion coupled to the second end portion 243 of the fan-out structure 222-1 and a second end portion coupled to the second surface 263 of the substrate 202. The material 208 is disposed on the connection (e.g., the connection point) between the bond wire 212-1 and the second end portion 243 of the fan-out structure 222-1. A portion 267 of the bond wire 212-1 may extend through the material 208.

The sensor package 200 includes a bond wire 212-2. The bond wire 212-2 includes a first end portion coupled to the second end portion of the fan-out structure 222-2 and a second end portion coupled to the first surface 261 of the substrate 202. The material 208 is disposed on the connection (e.g., the connection point) between the bond wire 212-2 and the second end portion of the fan-out structure 222-2. A portion of the bond wire 212-2 may extend through the material 208.

The radiation transmitting substrate 206 is coupled to the sensor module 204 via a material 208 such that the radiation transmitting substrate 206 is positioned over (and spaced apart from) the active region 258 on a surface of the sensor layer 201 in the direction A1. The material 208 may form dam members that position the radiation transmitting substrate 206 away from the active region 258. The radiation transmitting substrate 206 may be a substrate that enables photons or electromagnetic radiation such as radar, or light signals to pass through. The radiation transmitting substrate 206 includes an optically transparent material that allows electromagnetic radiation (e.g., light (e.g., visible light and near-infrared light), radar, or photons) to pass through (e.g., pass through the entirety of the material). In some examples, the radiation transmitting substrate 206 includes an optically transparent material that allows the transmission of light, radar, or photon waves without being scattered (or being scattered to a relatively small or negligible degree). In some examples, the radiation transmitting substrate 206 includes a cover. In some examples, the radiation transmitting substrate 206 includes one or more organic materials and/or one or more inorganic materials. In some examples, the radiation transmitting substrate 206 includes a glass material. In some examples, the radiation transmitting substrate 206 is a glass substrate. In some examples, the radiation transmitting substrate 206 includes one or more layers of transparent material.

The sensor package 200 includes an encapsulation material 216 configured to encapsulate one or more components of the sensor package 200. In some examples, the encapsulation material 216 is formed from a liquid encapsulation. In some examples, the encapsulation material 216 includes a molding material. The encapsulation material 216 includes one or more types of material (e.g., in a molding compound if including multiple types of materials) such as a metal, a plastic, a resin, an epoxy, a phenolic hardener, a silica material, a pigment, a glass, a ceramic casing, and/or so forth. The encapsulation material 216 may encapsulate the bond wires 212. The encapsulation material 216 may be disposed on the first surface 261 of the substrate 202. In some examples, the encapsulation material 216 may extend to an edge of the substrate 202 and contact edges (or a portion thereof) of the wafer substrate 221, the molding 220 (e.g., the molding portion 220-1, the molding portion 220-2), the material 208, and the radiation transmitting substrate 206.

The conductive components 218 are coupled to the substrate 202. In some examples, the conductive components 218 include conductive balls. In some examples, the conductive components 218 include solder balls. The conductive components 218 are configured to connect to an external device.

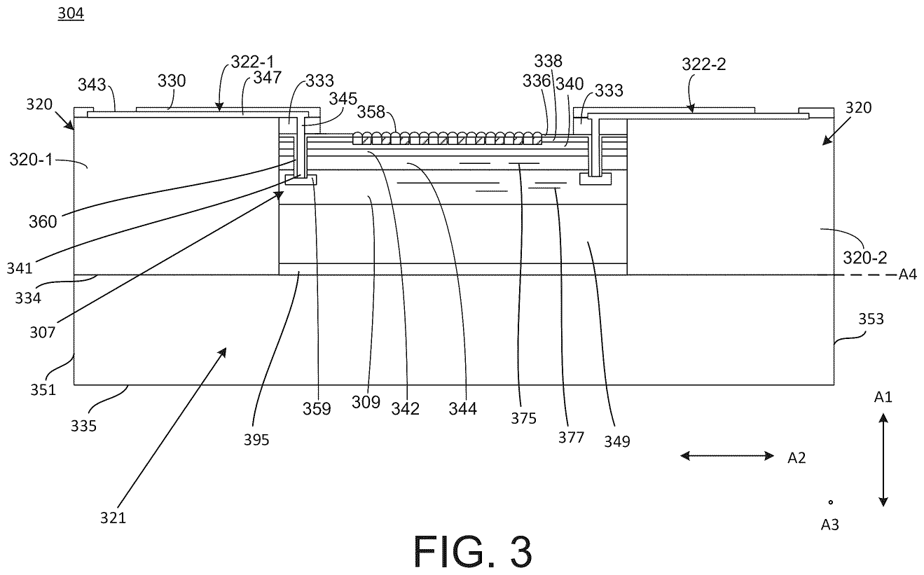

FIG. 3 illustrates an example of a sensor module 304 with an application-specific integrated circuit 307, a fan-out structure 322-1, and a fan-out structure 322-2 according to an aspect. In some examples, the sensor module 304 includes a fan-out wire-bond ball grid array structure with a CFA first. The sensor module 304 may be an example of the sensor module 204 of FIGS. 2A and 2B and may include any of the details discussed with reference to those figures.

In some examples, the image sensor module 304 may be, or referred to as, a sensor die (e.g., an image sensor die) or a sensor device (e.g., an image sensor device). In some examples, the sensor module 304 generates image data from light at an active region 358. However, the sensor module 304 may detect energy photons or electromagnetic radiation such as radar, or light signals. The sensor module 304 includes an application-specific integrated circuit 307 that is embedded into a structure of the sensor module 304. The sensor module 304 includes an active region 358, a protective layer 336, a layer 338, a passivation layer 340, a sensor layer 342 (e.g., an epitaxial silicon layer), a sensor layer 344 with metallic traces 375, an integrated circuit layer 309 with metallic traces 377, a layer 349, and an attachment layer 395. The active region 358 may have or correspond with, an array of pixel elements configured to convert electromagnetic radiation (e.g., light) to electrical signals.

The sensor module 304 includes a wafer substrate 321. In some examples, the wafer substrate 321 is a silicon substrate. In some examples, the wafer substrate 321 is an application-specific integrated circuit silicon substrate. The wafer substrate 321 includes a first surface 334 and a second surface 335. The first surface 334 is aligned in a plane A4. The wafer substrate 321 has a length in a direction A2, a width in a direction A3, and a thickness in a direction A1. The thickness may be defined between the first surface 334 and the second surface 335. A direction A1 is aligned perpendicular to the plane A4, and a direction A2 is perpendicular to the direction A1. A direction A3 is aligned parallel to the plane A4 and is orthogonal to directions A1 and A2. The layers (e.g., 336, 338, 340, 342, 344, 309, 395) have a length in a direction A2, a width in a direction A3, and a thickness in a direction A1. In some examples, the wafer substrate 321 has a length in the direction A2 that is greater than the length of the layers (e.g., 336, 338, 340, 342, 344, 309, 395).

The sensor module 304 is integrated with an application-specific integrated circuit 307. The application-specific integrated circuit 307 is integrated, embedded, or included within the structure of the sensor module 304. The application-specific integrated circuit 307 includes an integrated circuit layer 309 that is disposed below the sensor layer 344 in the direction A1.

The sensor module 304 includes a molding 320. The molding 320 is disposed on and contacts the first surface 334 of the wafer substrate 321. The molding 320 may be disposed on the wafer substrate 321 around the layers (e.g., 336, 338, 340, 342, 344, 309, 349, 395). The molding 320 includes a molding portion 320-1 that contacts the first surface 334 of a first portion of the wafer substrate 321. The molding portion 320-1 may contact edges of the layers (e.g., 336, 338, 340, 342, 344, 309, 349, 395). The molding portion 320-1 extends in the direction A2 to a location that aligns (e.g., corresponds to) with a first edge 351 of the wafer substrate 321 in the direction A1. The wafer substrate 321 includes a second edge 353 that is opposite to the first edge 351 in the direction A2.

The molding 320 includes a molding portion 320-2 disposed on another portion of the wafer substrate 321. The molding portion 320-2 may have the same structure as the molding portion 320-1, and, therefore, may include any of the details discussed with reference to the molding portion 320-1. The molding portion 320-2 contacts the first surface 334 of a second portion of the wafer substrate 321. The molding portion 320-2 may contact the other edges of the layers (e.g., 336, 338, 340, 342, 344, 309, 349, 349).

The sensor module 304 includes a fan-out structure 322-1 and a fan-out structure 322-2. The fan-out structures (e.g., 322-1, 322-2) connect the application-specific integrated circuit 307 to a bond wire connection point (e.g., where bond wires are connected to) that is located away from the active region 358. The fan-out structures (e.g., 322-1, 322-2) include one or more conductive portions (e.g., metallic portions) that are connected to the application-specific integrated circuit 307, extend through the protective layer 336, the layer 338, the passivation layer 340, the sensor layer 342 (e.g., epitaxial silicon layer), and the sensor layer 344, and extend along (and contact) a molding portion (e.g., molding portion 320-1, molding portion 320-2) to a location near the edge of the sensor module 304 in the direction A2.

The fan-out structure 322-1 includes a first end portion 341 and a second end portion 343. The first end portion 341 is connected to a contact terminal 359 of the application-specific integrated circuit 307. The second end portion 343 is located on the molding portion 320-1 at a first location that is away from the active region 358. The second end portion 343 may be exposed through a protective layer 330.

The sensor module 304 includes a hole 360 that extends through the protective layer 336, the layer 338, the passivation layer 340, the sensor layer 342 (e.g., an epitaxial silicon layer), and the sensor layer 344. In some examples, the hole 360 extends through a portion of the integrated circuit layer 309. In some examples, a hole 360 includes a probe pad hole.

The fan-out structure 322-1 includes a conductive portion 345 that extends in the hole 360 in the direction A1. In some examples, the hole 360 exposes the contact terminal 359 of the application-specific integrated circuit 307. The conductive portion 345 is connected to the contact terminal 359. In some examples, the conductive portion 345 is a linear portion.

The fan-out structure 322-1 includes a conductive portion 347 that extends from the conductive portion 345. The conductive portion 347 extends along the molding portion 320-1 in the direction A2. In some examples, the conductive portion 347 and the conductive portion 345 are perpendicular to each other. In some examples, a protective layer 330 covers the conductive portion 347, but the second end portion 343 of the fan-out structure 322-1 is exposed through the protective layer 330. In some examples, the sensor module 304 includes a layer portion 333 disposed between the protective layer 330 and the layer 336. The fan-out structure 322-2 may have the same structure as the fan-out structure 322-1, and, therefore, may include any of the details discussed with reference to the fan-out structure 322-1.

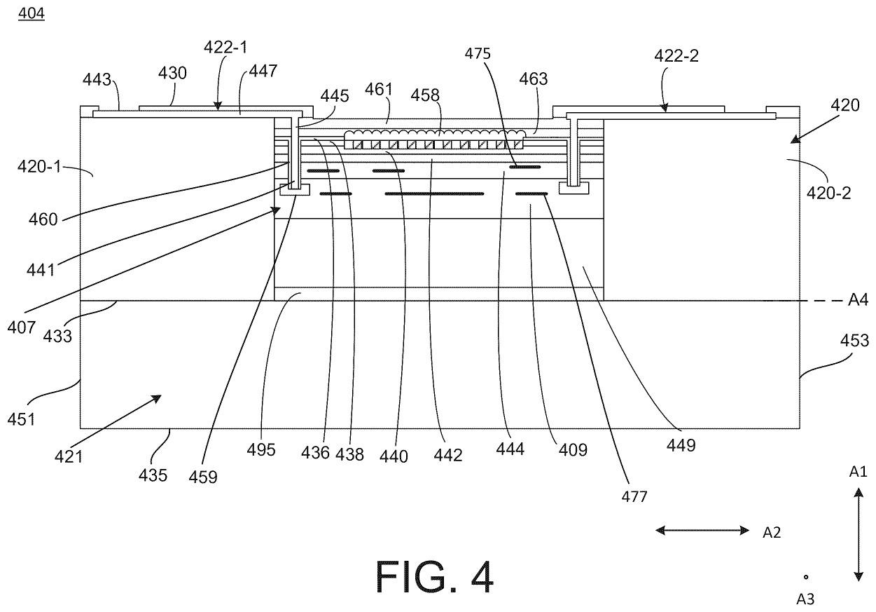

FIG. 4 illustrates an example of a sensor module 404 with an application-specific integrated circuit 407, a fan-out structure 422-1, and a fan-out structure 422-2 according to an aspect. In some examples, the sensor module 404 includes a fan-out wire-bond ball grid array structure with a CFA first and permanent protection over array. The sensor module 404 may be an example of the sensor module 204 of FIGS. 2A and 2B and/or the sensor module 304 of FIG. 3 and may include any of the details discussed with reference to those figures. The sensor module 404 may be the same as the sensor module 304 except that a layer 461 and a layer 463 are used instead of layer portion 333 as shown in FIG. 3.

In some examples, the image sensor module 404 may be, or referred to as, a sensor die (e.g., an image sensor die) or a sensor device (e.g., an image sensor device). In some examples, the sensor module 404 generates image data from light at an active region 458. However, the sensor module 404 may detect energy photons or electromagnetic radiation such as radar, or light signals. The sensor module 404 includes an application-specific integrated circuit 407 that is embedded into a structure of the sensor module 404. The sensor module 404 includes an active region 458, a protective layer 436, a layer 438, a passivation layer 440, a sensor layer 442 (e.g., an epitaxial silicon layer), a sensor layer 444 with metallic traces 475, an integrated circuit layer 409 with metallic traces 477, a layer 449, and an attachment layer 495. The active region 458 may have or correspond with, an array of pixel elements configured to convert electromagnetic radiation (e.g., light) to electrical signals. The sensor module 404 includes a layer 463 disposed on the protective layer 436. The sensor module 404 includes a layer 461 disposed on the layer 463.

The sensor module 404 includes a wafer substrate 421. In some examples, the wafer substrate 421 is a silicon substrate. In some examples, the wafer substrate 421 is an application-specific integrated circuit silicon substrate. The wafer substrate 421 includes a first surface 433 and a second surface 435. The first surface 433 is aligned in a plane A4. The wafer substrate 421 has a length in a direction A2, a width in a direction A3, and a thickness in a direction A1. The thickness may be defined between the first surface 433 and the second surface 435. A direction A1 is aligned perpendicular to the plane A4, and a direction A2 is perpendicular to the direction A1. A direction A3 is aligned parallel to the plane A4 and is orthogonal to directions A1 and A2. The layers (e.g., 461, 463, 436, 438, 440, 442, 444, 409, 449, 495) have a length in a direction A2, a width in a direction A3, and a thickness in a direction A1. In some examples, the wafer substrate 421 has a length in the direction A2 that is greater than the length of the layers (e.g., 461, 463, 436, 438, 440, 442, 444, 409, 449, 495).

The sensor module 404 is integrated with an application-specific integrated circuit 407. The application-specific integrated circuit 407 is integrated, embedded, or included within the structure of the sensor module 404. The application-specific integrated circuit 407 includes an integrated circuit layer 409 that is disposed below the sensor layer 444 in the direction A1.

The sensor module 404 includes a molding 420. The molding 420 is disposed on and contacts the first surface 433 of the wafer substrate 421. The molding 420 may be disposed on the wafer substrate 421 around the layers (e.g., 461, 463, 436, 438, 440, 442, 444, 409, 449, 495). The molding 420 includes a molding portion 420-1 that contacts the first surface 433 of a first portion of the wafer substrate 421. The molding portion 420-1 may contact edges of the layers (e.g., 461, 463, 436, 438, 440, 442, 444, 409, 495). The molding portion 420-1 extends in the direction A2 to a location that aligns (e.g., corresponds to) with a first edge 451 of the wafer substrate 421 in the direction A1. The wafer substrate 421 includes a second edge 453 that is opposite to the first edge 451.

The molding 420 includes a molding portion 420-2 disposed on another portion of the wafer substrate 421. The molding portion 420-2 may have the same structure as the molding portion 420-1, and, therefore, may include any of the details discussed with reference to the molding portion 420-1. The molding portion 420-2 contacts the first surface 433 of a second portion of the wafer substrate 421. The molding portion 420-2 may contact the other edges of the layers (e.g., 461, 463, 436, 438, 440, 442, 444, 409, 495).

The sensor module 404 includes a fan-out structure 422-1 and a fan-out structure 422-2. The fan-out structures (e.g., 422-1, 422-2) connect the application-specific integrated circuit 407 to a bond-wire connection point (e.g., where bond wires are connected to) that is located away from the active region 458. The fan-out structures (e.g., 422-1, 422-2) include one or more conductive portions (e.g., metallic portions) that are connected to the application-specific integrated circuit 407, extend through the layer 461, the layer 463, the protective layer 436, the layer 438, the passivation layer 440, the sensor layer 442 (e.g., epitaxial silicon layer), and the sensor layer 444, and extend along (and contact) a molding portion (e.g., molding portion 420-1, molding portion 420-2) to a location near the edge of the sensor module 404.

The fan-out structure 422-1 includes a first end portion 441 and a second end portion 443. The first end portion 441 is connected to a contact terminal 459 of the application-specific integrated circuit 407. The second end portion 443 is located on the molding portion 420-1 at a first location that is away from the active region 458. The second end portion 443 may be exposed through a protective layer 430 that covers portions of the fan-out structure 422-1.

The sensor module 404 includes a hole 460 that extends through the layer 461, the layer 463, the protective layer 436, the layer 438, the passivation layer 440, the sensor layer 442 (e.g., an epitaxial silicon layer), and the sensor layer 444. In some examples, the hole 460 extends through a portion of the integrated circuit layer 409.

The fan-out structure 422-1 includes a conductive portion 445 that extends in the hole 460 in the direction A1. In some examples, the hole 460 exposes the contact terminal 459 of the application-specific integrated circuit 407. The conductive portion 445 is connected to the contact terminal 459. In some examples, the conductive portion 445 is a linear portion.

The fan-out structure 422-1 includes a conductive portion 447 that extends from the conductive portion 445. In some examples, the conductive portion 445 and the conductive portion 447 form a continuous conductive trace or line. The conductive portion 447 extends along the molding portion 420-1 in the direction A2. In some examples, the conductive portion 447 and the conductive portion 445 are perpendicular to each other. In some examples, a protective layer 430 covers the conductive portion 447, but the second end portion 443 of the fan-out structure 422-1 is exposed through the protective layer 430. The fan-out structure 422-2 may have the same structure as the fan-out structure 422-1, and, therefore, may include any of the details discussed with reference to the fan-out structure 422-1.

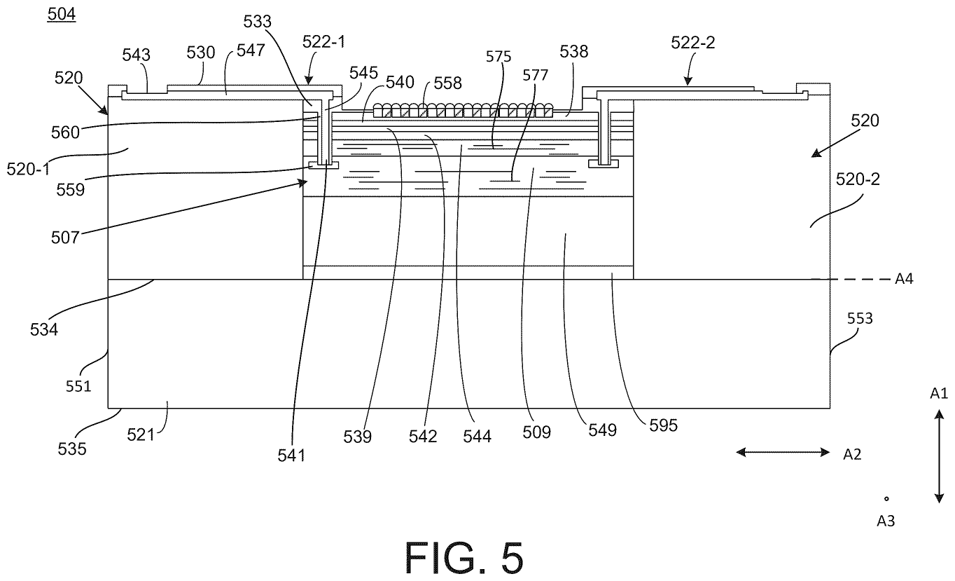

FIG. 5 illustrates an example of a sensor module 504 with an application-specific integrated circuit 507, a fan-out structure 522-1, and a fan-out structure 522-2 according to an aspect. In some examples, the sensor module 504 includes a fan-out wire-bond ball grid array structure with a CFA last. The sensor module 504 may be an example of the sensor module 204 of FIGS. 2A and 2B, the sensor module 304 of FIG. 4, and/or the sensor module 404 of FIG. 4 and may include any of the details discussed with reference to those figures.

In some examples, the image sensor module 504 may be, or referred to as, a sensor die (e.g., an image sensor die) or a sensor device (e.g., an image sensor device). In some examples, the sensor module 504 generates image data from light at an active region 558. However, the sensor module 504 may detect energy photons or electromagnetic radiation such as radar, or light signals. The sensor module 504 includes an application-specific integrated circuit 507 that is embedded into a structure of the sensor module 504. The sensor module 504 includes an active region 558, a protective layer 533, a layer 538, a passivation layer 540, a sensor layer 542 (e.g., epitaxial silicon layer), a layer 539, a sensor layer 544 with metallic traces 575, an integrated circuit layer 509 with metallic traces 577, a layer 549, and an attachment layer 595. The active region 558 may have or correspond with, an array of pixel elements configured to convert electromagnetic radiation (e.g., light) to electrical signals.

The sensor module 504 includes a wafer substrate 521. In some examples, the wafer substrate 521 is a silicon substrate. In some examples, the wafer substrate 521 is an application-specific integrated circuit silicon substrate. The wafer substrate 521 includes a first surface 534 and a second surface 535. The first surface 534 is aligned in a plane A4. The wafer substrate 521 has a length in a direction A2, a width in a direction A3, and a thickness in a direction A1. The thickness may be defined between the first surface 534 and the second surface 535. A direction A1 is aligned perpendicular to the plane A4, and a direction A2 is perpendicular to the direction A1. A direction A3 is aligned parallel to the plane A4 and is orthogonal to directions A1 and A2.

The sensor module 504 is integrated with an application-specific integrated circuit 507. The application-specific integrated circuit 507 is integrated, embedded, or included within the structure of the sensor module 504. The application-specific integrated circuit 507 includes an integrated circuit layer 509 that is disposed below the sensor layer 544 in the direction A1.

The sensor module 504 includes a molding 520. The molding 520 is disposed on and contacts the first surface 534 of the wafer substrate 521. The molding 520 may be disposed on the wafer substrate 521 around the sensor and integrated circuit layers. The molding 520 includes a molding portion 520-1 that contacts the first surface 534 of a first portion of the wafer substrate 521. The molding portion 520-1 may contact edges of the sensor and integrated circuit layers. The molding portion 520-1 extends in the direction A2 to a location that aligns (e.g., corresponds to) with a first edge 551 of the wafer substrate 521 in the direction A1. The wafer substrate 521 includes a second edge 553 that is opposite to the first edge 551.

The molding 520 includes a molding portion 520-2 disposed on another portion of the wafer substrate 521. The molding portion 520-2 may have the same structure as the molding portion 520-1, and, therefore, may include any of the details discussed with reference to the molding portion 520-1. The molding portion 520-2 contacts the first surface 534 of a second portion of the wafer substrate 521. The molding portion 520-2 may contact the other edges of the sensor and integrated circuit layers.

The sensor module 504 includes a fan-out structure 522-1 and a fan-out structure 522-2. The fan-out structures (e.g., 522-1, 522-2) connect the application-specific integrated circuit 507 to a bond-wire connection point (e.g., where bond wires are connected to) that is located away from the active region 558. The fan-out structures (e.g., 522-1, 522-2) include one or more conductive portions (e.g., metallic portions) that are connected to the application-specific integrated circuit 507, extend through the protective layer 533, the layer 538, the passivation layer 540, the sensor layer 542 (e.g., epitaxial silicon layer), and the sensor layer 544, and extend along (and contact) a molding portion (e.g., molding portion 520-1, molding portion 520-2) to a location near the edge of the sensor module 504.

The fan-out structure 522-1 includes a first end portion 541 and a second end portion 543. The first end portion 541 is connected to a contact terminal 559 of the application-specific integrated circuit 507. The second end portion 543 is located on the molding portion 520-1 at a first location that is away from the active region 558. The second end portion 543 may be exposed through a protective layer 530.

The sensor module 504 includes a hole 560 that extends through the protective layer 533, the layer 538, the passivation layer 540, the sensor layer 542 (e.g., epitaxial silicon layer), and the sensor layer 544. In some examples, the hole 560 extends through a portion of the integrated circuit layer 509 and exposes the contact terminal 559. The fan-out structure 522-1 includes a conductive portion 545 that extends in the hole 560 in the direction A1. The conductive portion 545 is connected to the contact terminal 559. In some examples, the conductive portion 545 is a linear portion.

The fan-out structure 522-1 includes a conductive portion 547 that extends from the conductive portion 545. The conductive portion 547 extends along the molding portion 520-1 in the direction A2. In some examples, the conductive portion 547 and the conductive portion 545 are perpendicular to each other. In some examples, a protective layer 530 covers the conductive portion 547, but the second end portion 543 of the fan-out structure 522-1 is exposed through the protective layer 530 to connect to a bond wire or other connection point. The fan-out structure 522-2 may have the same structure as the fan-out structure 522-1, and, therefore, may include any of the details discussed with reference to the fan-out structure 522-1.

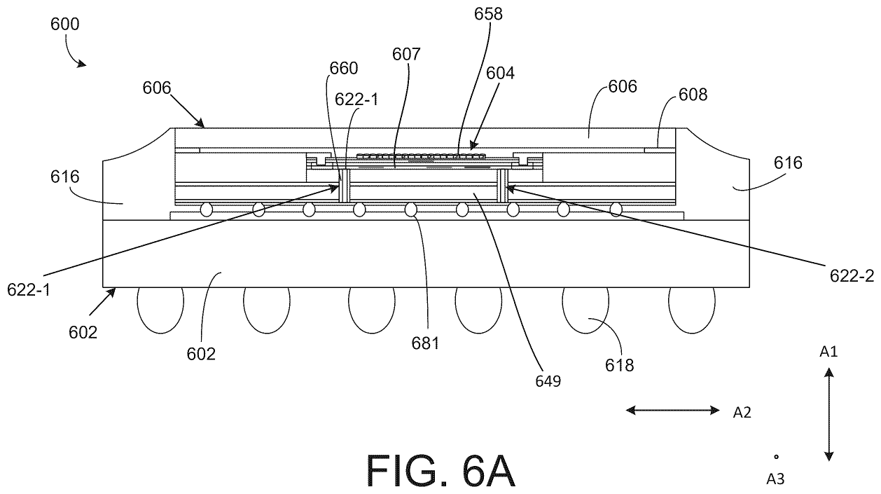

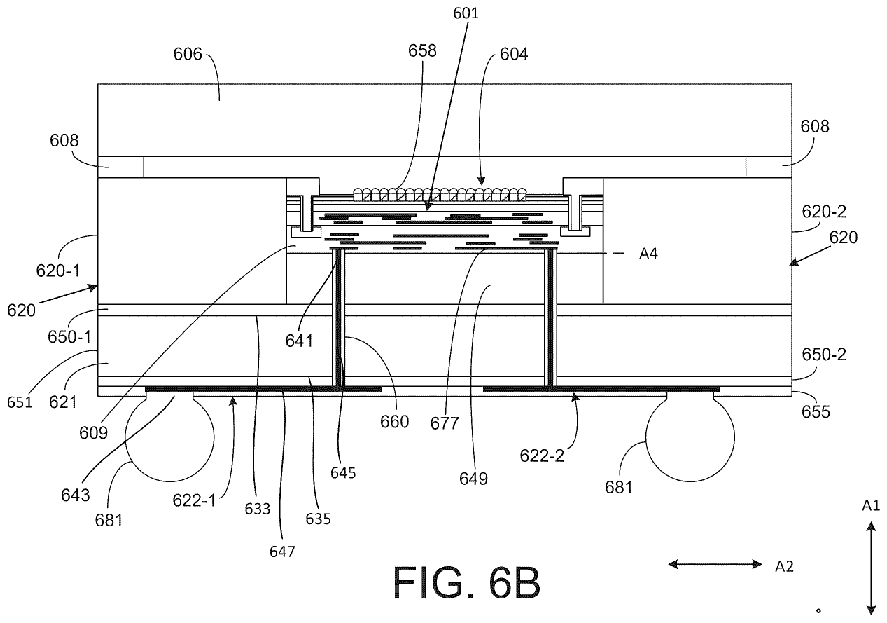

FIGS. 6A and B illustrate an example of a sensor package 600 having a sensor module 604 with an application-specific integrated circuit 607, a fan-out structure 622-1, and a fan-out structure 622-2 according to an aspect. The fan-out structures (e.g., 622-1, 622-2) connect to the application-specific integrated circuit 607 to a conductive component 681 through a backside of the sensor module 604.

The sensor package 600 includes a substrate 602, a sensor module 604 coupled to the substrate 602, and a radiation transmitting substrate 606 coupled to the sensor module 604 via an material 608. The sensor package 600 includes a plurality of conductive components 618 coupled to the substrate 602.

In some examples, the image sensor module 604 may be, or referred to as, a sensor die (e.g., an image sensor die) or a sensor device (e.g., an image sensor device). In some examples, the sensor module 604 generates image data from light at an active region 658. However, the sensor module 604 may detect energy photons or electromagnetic radiation such as radar, or light signals. The sensor module 604 includes an application-specific integrated circuit 607 that is embedded into a structure of the sensor module 604. The sensor module 604 includes an active region 658, one or more sensor layers 601, one or more integrated circuit layers 609, and a layer 649. The active region 658 may have or correspond with, an array of pixel elements configured to convert electromagnetic radiation (e.g., light) to electrical signals. The sensor module 604 may include any one or more of the other layers as discussed with reference to other figures.

The sensor module 604 includes a wafer substrate 621. In some examples, the wafer substrate 621 is a silicon substrate. The wafer substrate 621 includes a first surface 633 and a second surface 635. The first surface 633 is aligned in a plane A4. The wafer substrate 621 has a length in a direction A2, a width in a direction A3, and a thickness in a direction A1. The thickness may be defined between the first surface 633 and the second surface 635. A direction A1 is aligned perpendicular to the plane A4, and a direction A2 is perpendicular to the direction A1. A direction A3 is aligned parallel to the plane A4 and is orthogonal to directions A1 and A2.

The sensor module 604 is integrated with an application-specific integrated circuit 607. The application-specific integrated circuit 607 is integrated, embedded, or included within the structure of the sensor module 604. The application-specific integrated circuit 607 includes an integrated circuit layer 609 that is disposed below the sensor layer 601 in the direction A1. The integrated circuit layer 609 includes metallic traces, which one or more may function as a contact terminal.

The sensor module 604 includes a molding 620. The molding 620 is disposed on and contacts the first surface 633 of the wafer substrate 621. The molding 620 may be disposed on the wafer substrate 621 around the integrated circuit layer 609, the sensor layer 601, and the layer 649. The molding 620 includes a molding portion 620-1 that contacts a first surface 633 of a first portion of the wafer substrate 621. The molding portion 620-1 may contact edges of the integrated circuit layer 609, the sensor layer 601, and the layer 649. The molding portion 620-1 extends in the direction A2 to a location that aligns (e.g., corresponds to) with an edge 651 of the wafer substrate 621 in the direction A1.

The molding 620 includes a molding portion 620-2 disposed on another portion of the wafer substrate 621. The molding portion 620-2 may have the same structure as the molding portion 620-1, and, therefore, may include any of the details discussed with reference to the molding portion 620-1. The molding portion 620-2 contacts the first surface 633 of a second portion of the wafer substrate 621. The molding portion 620-2 may contact the other edges of the integrated circuit layer 609, the sensor layer 601, and the layer 649.

The sensor module 604 includes an adhesive layer 650-1 that couples the wafer substrate 621 to the molding portion 620-1, the molding portion 620-2, and the layer 649. The sensor module 604 includes a layer 655 with a plurality of conductive components 681, and the layer 655 is coupled to the wafer substrate 621 via an adhesive layer 650-2. In some examples, the conductive components 681 are conductive balls (e.g., solder balls).

The sensor module 604 includes a fan-out structure 622-1 and a fan-out structure 622-2. The fan-out structures (e.g., 622-1, 622-2) connect the application-specific integrated circuit 607 to the conductive components 681 on a backside of the sensor module 604. The fan-out structures (e.g., 622-1, 622-2) include one or more conductive portions (e.g., metallic portions) that are connected to the application-specific integrated circuit 607, extend through the integrated circuit layer 609, the layer 649, the wafer substrate 621 in the direction A1, extend along a surface of the wafer substrate 621 in the direction A2, and connect to the conductive components 681.

The fan-out structure 622-1 includes a first end portion 641 and a second end portion 643. The first end portion 641 is connected to a conductive portion 677 (e.g., a contact terminal) of the integrated circuit layer 609. The second end portion 643 is located on the backside of the wafer substrate 621. The second end portion 643 is connected to a conductive component 681. The sensor module 604 includes a hole 660 that extends through the layer 649 and the wafer substrate 621. In some examples, the hole 660 extends through a portion of the integrated circuit layer 609.

The fan-out structure 622-1 includes a conductive portion 645 that extends in the hole 660 in the direction A1. The conductive portion 645 is connected to the conductive portion 677 (e.g., a contact terminal) of the integrated circuit layer 709. In some examples, the conductive portion 645 is a linear portion.

The fan-out structure 622-1 includes a conductive portion 647 that extends from the conductive portion 645. The conductive portion 647 extends along the wafer substrate 621 in the direction A2. In some examples, the conductive portion 647 and the conductive portion 645 are perpendicular to each other. The fan-out structure 622-2 may have the same structure as the fan-out structure 622-1, and, therefore, may include any of the details discussed with reference to the fan-out structure 622-1.

The sensor package 600 includes a substrate 602 coupled to the sensor module 604. The substrate 202 is coupled to the wafer substrate 221 via the conductive components 681. The substrate 602 may have a length in the direction A2, a width in a direction A3, and a thickness in a direction A1. The substrate 602 includes a dielectric layer. The dielectric layer includes an insulating material. In some examples, the dielectric layer includes a ceramic material. In some examples, the substrate 602 includes a single dielectric layer. In some examples, the substrate 602 includes multiple dielectric layers. In some examples, the substrate 602 includes a printed circuit board (PCB) substrate (e.g., a single layer of PCB or multiple layers of PCB).

The radiation transmitting substrate 606 is coupled to the sensor module 604 via a material 608 such that the radiation transmitting substrate 606 is positioned over (and spaced apart from) the active region 658 in the direction A1. IN some examples, the material 608 forms one or more dam members that space the radiation transmitting substrate 606 away from the active region 658 in the direction A1. The radiation transmitting substrate 606 may be a substrate that enables photons or electromagnetic radiation such as radar, or light signals to pass through. The radiation transmitting substrate 606 includes an optically transparent material that allows electromagnetic radiation (e.g., light (e.g., visible light, near-infrared light), photons, radar, etc.) to pass through (e.g., pass through the entirety of the material). In some examples, the radiation transmitting substrate 606 includes an optically transparent material that allows the transmission of light, radar, or photons without being scattered (or being scattered to a relatively small or negligible degree). In some examples, the radiation transmitting substrate 606 includes one or more organic materials and/or one or more inorganic materials. In some examples, the radiation transmitting substrate 606 includes a glass material. In some examples, the radiation transmitting substrate 606 is a glass substrate. In some examples, the radiation transmitting substrate 606 includes one or more layers of transparent material.

The sensor package 600 includes an encapsulation material 616 configured to encapsulate one or more components of the sensor package 600. In some examples, the encapsulation material 616 is formed from a liquid encapsulation. In some examples, the encapsulation material 616 includes a molding material. The encapsulation material 616 includes one or more types of material (e.g., in a molding compound if including multiple types of materials) such as a metal, a plastic, a resin, an epoxy, a phenolic hardener, a silica material, a pigment, a glass, a ceramic casing, and/or so forth. The encapsulation material 616 may be disposed on the first surface of the substrate 602. The conductive components 618 are coupled to the substrate 602. In some examples, the conductive components 618 include conductive balls. In some examples, the conductive components 618 include solder balls. The conductive components 618 are configured to connect to an external device.

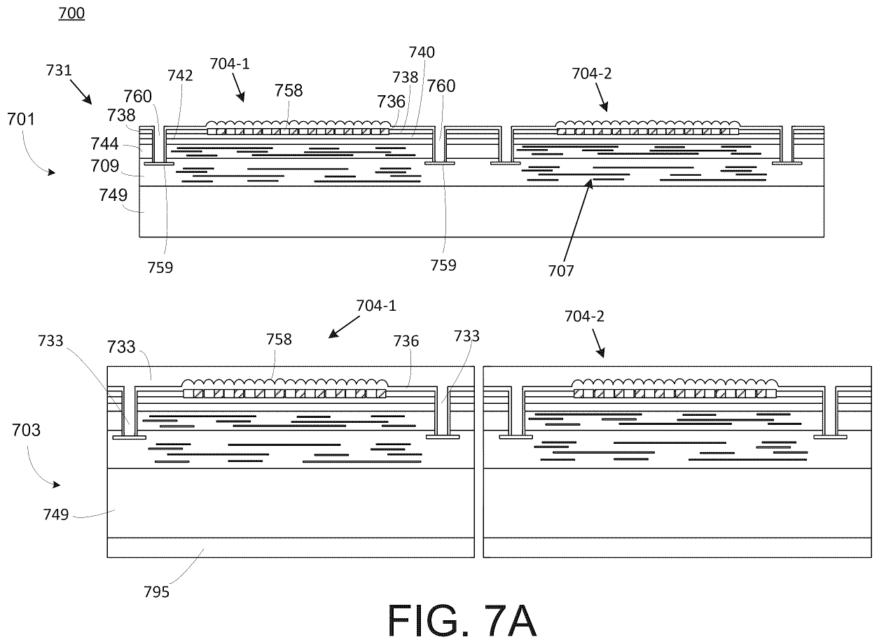

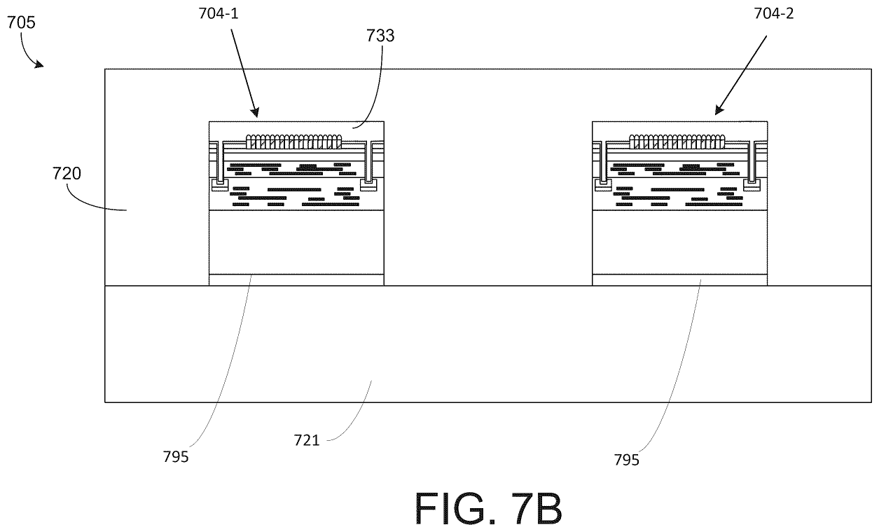

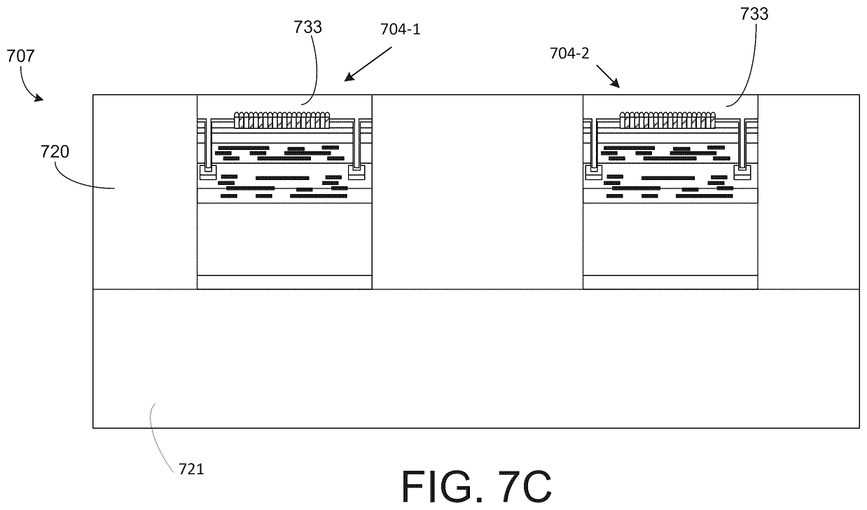

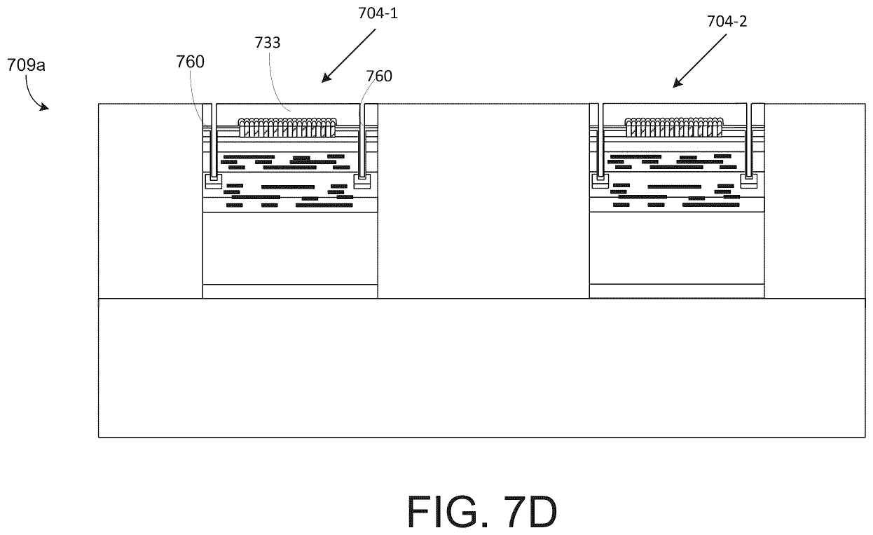

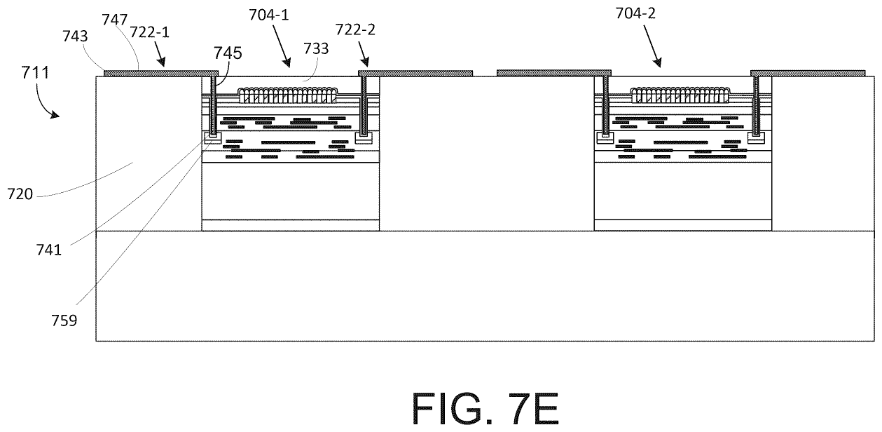

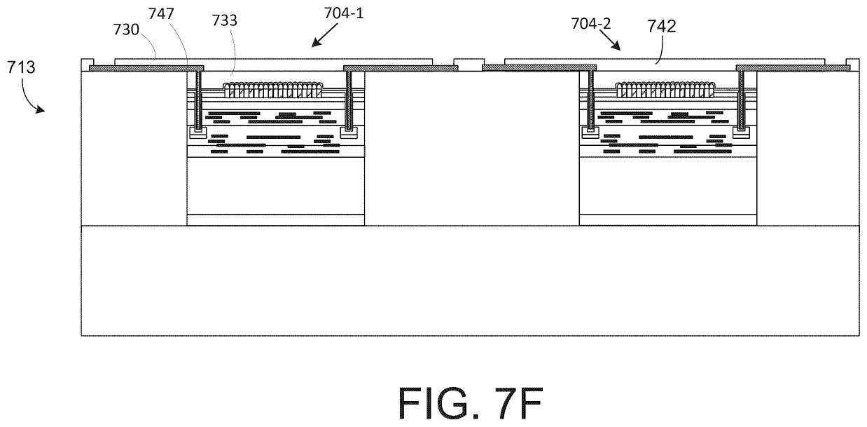

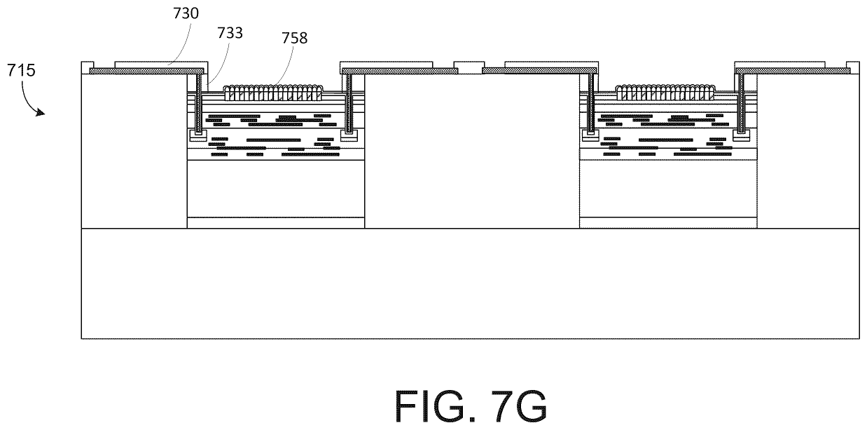

FIGS. 7A to 7G illustrate a process 700 for generating a sensor module according to an aspect. In some examples, the process 700 of FIGS. 7A to 7G depicts example operations of generating the sensor module 304 of FIG. 3. However, the process 700 of FIGS. 7A to 7G may be applicable to other implementations discussed herein.

Referring to FIG. 7A, operation 701 includes receiving a sensor substrate assembly 731. The sensor substrate assembly 731 may include multiple sensor modules such as a sensor module 704-1 and a sensor module 704-2. In operation 701, the sensor substrate assembly 731 may be a single substrate in which the sensor module 704-1 and the sensor module 704-2 are not separated yet.

The sensor substrate assembly 731 includes a protective layer 736, a layer 738, a passivation layer 740, a sensor layer 742 (e.g., epitaxial silicon layer), a sensor layer 744 with metallic traces, an integrated circuit layer 709 with metallic traces, and a layer 749. For each sensor module, the sensor substrate assembly 731 includes an active region 758 and holes 760 (e.g., two holes). A hole 760 extends through the protective layer 736, the layer 738, the passivation layer 740, the sensor layer 742 (e.g., epitaxial silicon layer), and the sensor layer 744. In some examples, the hole 360 extends through a portion of the integrated circuit layer 709. Each sensor module (e.g., 704-1, 704-2) includes an application-specific integrated circuit 307 that is embedded into a structure of a respective sensor module. The application-specific integrated circuit includes an integrated circuit layer 709 that is disposed below the sensor layer 744. The integrated circuit layer 709 includes a contact terminal 759, which is exposed by the hole 760.

Operation 703 includes depositing a protective layer 733 to the active region 758, the protective layer 736, and to (and within) the holes 760. In some examples, the protective layer 733 includes a spin-coat organic protective layer. In some examples, the protective layer 733 may cover the surface (e.g., the entire surface) including filling up the holes 760. In some examples, the protective layer 733 may temporarily remain on the sidewall of the holes 760 and the portions of the protective layer 733 in the hole 760 may be removed later in the process. In some examples, a silicon nitride stop layer may be deposited at this stage. In some examples, operation 703 includes coupling an attachment layer 795 to the sensor substrate assembly 731 (e.g., the attachment layer 795 is applied to the layer 749). In some examples, the attachment layer 795 includes a die attach film (DAF). In some examples, operation 703 includes dicing the sensor substrate assembly 731 to separate the sensor module 704-1 and the sensor module 704-2.

Referring to FIG. 7B, operation 705 includes attaching a wafer substrate 721 to the attachment layer 795 and applying a molding 320 over the surface (e.g., the entire surface) to fill in gaps between the dies (e.g., the sensor module 704-1, sensor module 704-2) and cure the molding 320.

Referring to FIG. 7C, operation 707 includes removing a portion of the molding 720 and a portion the protective layer 733. Referring to FIG. 7D, operation 709a includes performing a photolithography and etch process to create an opening in the hole 760. In other words, the protective layer 733 may be at least partially removed from the hole 760. In some examples, a thin layer of the protective layer 733 remains on the sidewall of the hole 760. Referring to FIG. 7E, operation 711 includes forming fan-out structures (e.g., 722-1, 722-2) on each of sensor module 704-1 and sensor module 704-2. In some examples, operation 711 includes depositing a conductive material (e.g., Ti/Al or Ta/Cu) and performing a fan-Out Photolithography and etching process to create the redistribution layer and wire bond pad.

The fan-out structure 722-1 includes a first end portion 741 and a second end portion 743. The first end portion 741 is connected to a contact terminal 759 of the application-specific integrated circuit. The second end portion 743 is located on the molding 720 at a location that is away from the active region 758. The fan-out structure 722-1 includes a conductive portion 745 that extends in the hole 760 in a first direction. The fan-out structure 722-1 includes a conductive portion 747 that extends from the conductive portion 745. The conductive portion 747 extends along the molding 320 in a second direction. In some examples, the conductive portion 747 and the conductive portion 745 are perpendicular to each other.

Referring to FIG. 7F, operation 713 includes applying a passivation layer 730 to portions of the fan-out structures and the passivation layer 730. In some examples, operation 713 includes forming a spin coat organic dielectric passivation layer (e.g., a non-reflecting, absorbing black material) to form the passivation layer 730 and forming an opening to expose the wire bond pad (e.g., the second end portion 743). Referring to FIG. 7G, operation 715 includes removing portions of the passivation layer 730 and removing portions of the protective layer 733. In some examples, operation 715 includes performing a photolithography and etch process to remove organic passivation from the active region 758.

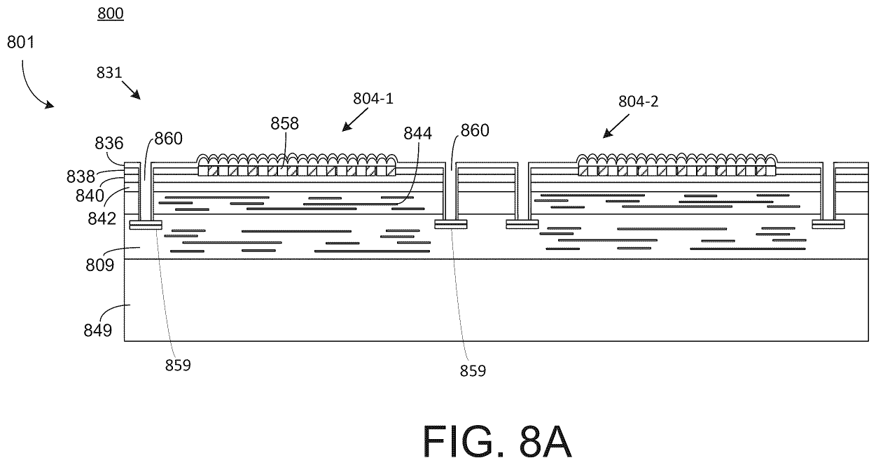

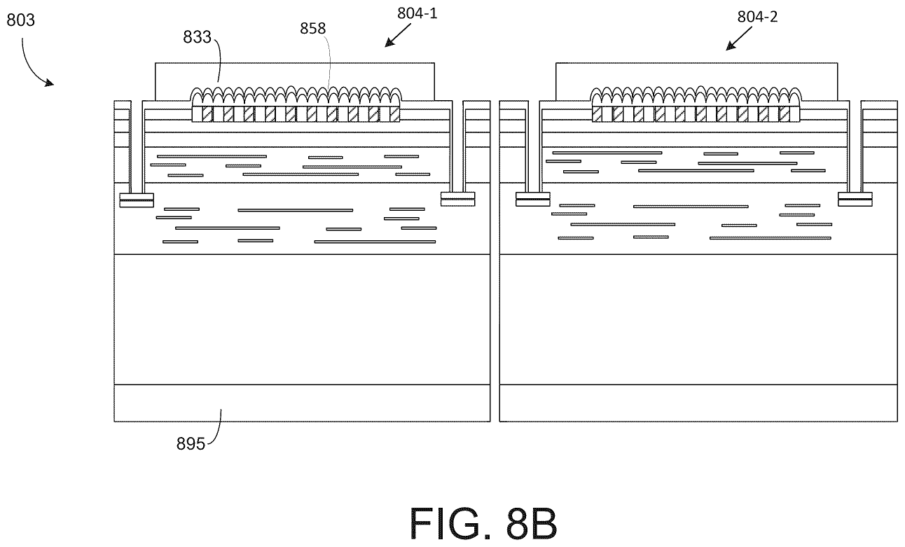

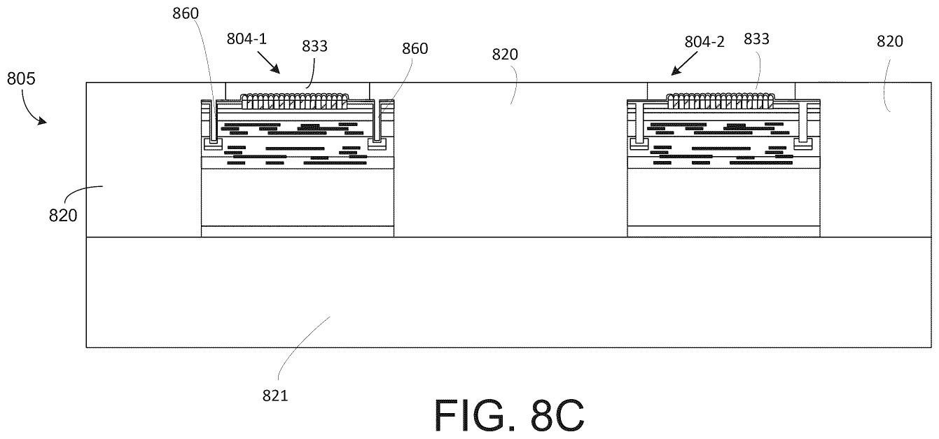

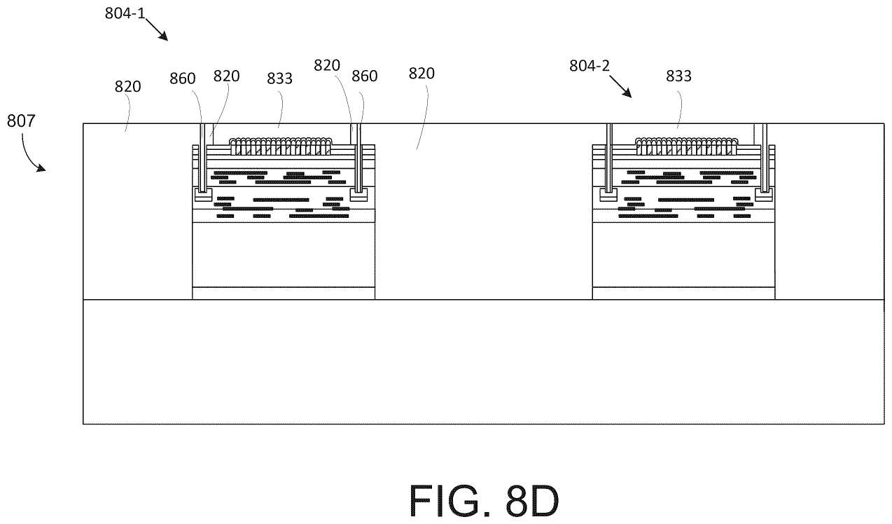

FIGS. 8A to 8D illustrate a process 800 for generating a sensor module according to an aspect. In some examples, the process of FIGS. 8A to 8D depicts example alternative operations for some of the operation steps for generating the sensor module 304 of FIG. 3 and/or some of the operation steps of FIGS. 7A to 7F. However, the process 800 of FIGS. 8A to 8D may be applicable to other implementations discussed herein.

Referring to FIG. 8A, operation 801 includes receiving a sensor substrate assembly 831. The sensor substrate assembly 831 may include multiple sensor modules such as a sensor module 804-1 and a sensor module 804-2. In operation 801, the sensor substrate assembly 831 may be a single substrate in which the sensor module 804-1 and the sensor module 804-2 are not separated yet.

The sensor substrate assembly 831 includes a protective layer 836, a layer 838, a passivation layer 840, a sensor layer 842 (e.g., epitaxial silicon layer), a sensor layer 844 with metallic traces, an integrated circuit layer 809 with metallic traces, and a layer 849. For each sensor module, the sensor substrate assembly 831 includes an active region 858 and holes 860 (e.g., two holes). A hole 860 extends through the protective layer 836, the layer 838, the passivation layer 840, the sensor layer 842 (e.g., epitaxial silicon layer), and the sensor layer 844. In some examples, the hole 860 extends through a portion of the integrated circuit layer 809. Each sensor module (e.g., 804-1, 804-2) includes an application-specific integrated circuit that is embedded into a structure of a respective sensor module. The application-specific integrated circuit includes an integrated circuit layer 809 that is disposed below the sensor layer 844. The integrated circuit layer 809 includes a contact terminal 859, which is exposed by the hole 860.

Referring to FIG. 8B, operation 803 includes depositing a protective layer 833 over the active region 858 and portions of the protective layer 836. In some examples, the protective layer 833 includes a spin-coat organic protective layer. In some examples, operation 803 includes coupling an attachment layer 895 to the sensor substrate assembly 831 (e.g., the attachment layer 895 is applied to the layer 849). In some examples, the attachment layer 895 includes a die attach film (DAF). In some examples, operation 803 includes dicing the sensor substrate assembly 831 to separate the sensor module 804-1 and the sensor module 804-2.

Referring to FIG. 8C, operation 805 includes attaching a wafer substrate 821 to the attachment layer 895 and applying a molding 820 over the surface (e.g., the entire surface) to fill in gaps between the dies (e.g., the sensor module 804-1, sensor module 804-2) and to fill in the holes 860. Operation 805 includes curing the molding 820. Referring to FIG. 8D, operation 807 includes removing portions of the molding 720 from the holes 860. In some examples, operation 807 includes performing a photolithography and etch process to make an opening to the hole 860. Then, the process 800 may continue with the redistribution layer steps, e.g., continuing to operation 711 in FIG. 7E.

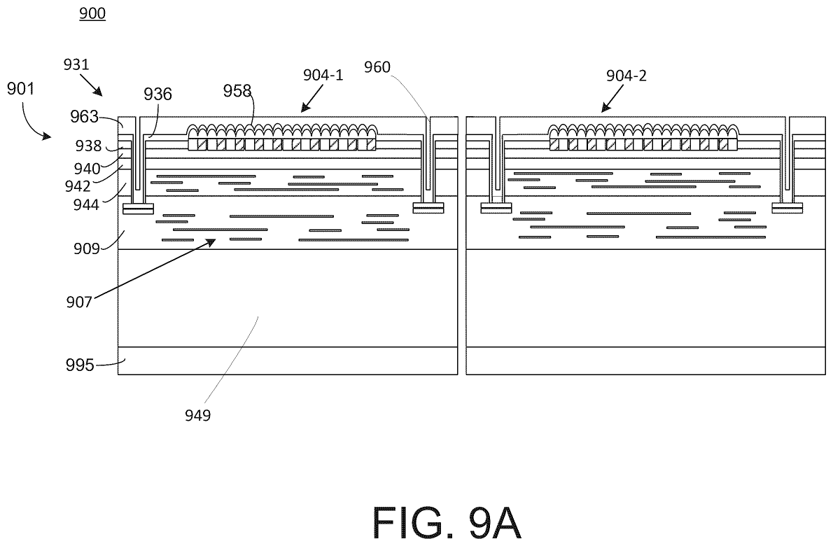

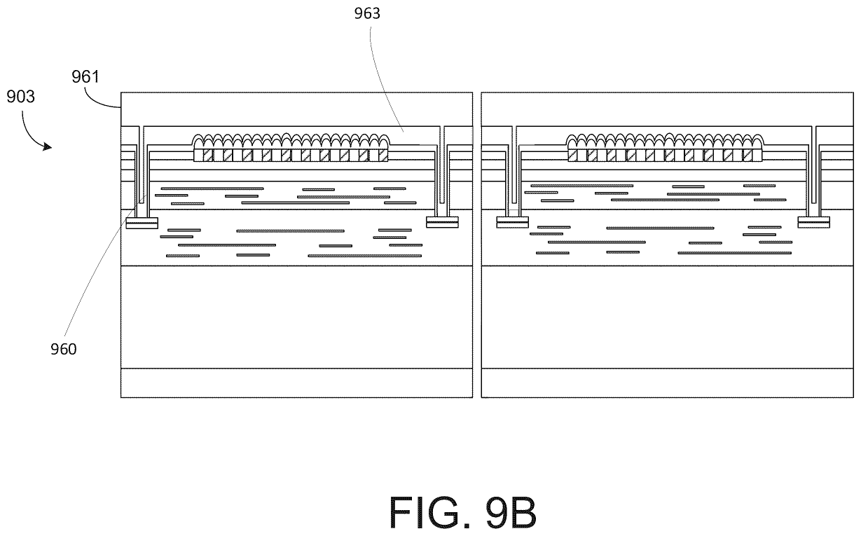

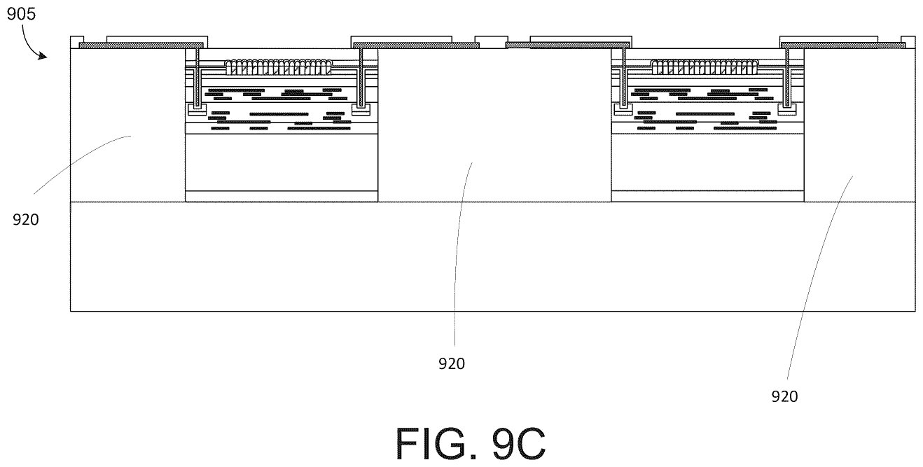

FIGS. 9A to 9C illustrate a process 900 for generating a sensor module according to an aspect. In some examples, the process 900 of FIGS. 9A to 9C depicts example operations of generating the sensor module 404 of FIG. 4. However, the process 900 of FIGS. 9A to 9C may be applicable to other implementations discussed herein.

Referring to FIG. 9A, operation 901 includes receiving a sensor substrate assembly 931. The sensor substrate assembly 931 may include multiple sensor modules such as a sensor module 904-1 and a sensor module 904-2. Operation 901 may include applying a layer 963 to the surface of the sensor module 904-1. In some examples, the layer 963 includes a permanent layer. In some examples, the layer 963 includes a spin-coat low refractive index layer.

The sensor module 904-1 includes an active region 958, a protective layer 936, a layer 938, a passivation layer 940, a sensor layer 942 (e.g., an epitaxial silicon layer), a sensor layer 944 with metallic traces, an integrated circuit layer 909 with metallic traces, a layer 949, and an attachment layer 995.

The sensor substrate assembly 931 includes 960. A hole 960 extends through the layer 963, the protective layer 936, the layer 938, the passivation layer 940, the sensor layer 942 (e.g., epitaxial silicon layer), and the sensor layer 944. In some examples, the hole 960 extends through a portion of the integrated circuit layer 909. Each sensor module (e.g., 904-1, 904-2) includes an application-specific integrated circuit 907 that is embedded into a structure of a respective sensor module. The application-specific integrated circuit 907 includes an integrated circuit layer 909 that is disposed below the sensor layer 944. The integrated circuit layer 909 includes a contact terminal, which is exposed by the hole 960.

Referring to FIG. 9B, operation 903 includes depositing a protective layer 961 to the layer 963 and to (and within) the holes 960. In some examples, the protective layer 963 includes a spin-coat organic protective layer. In some examples, the protective layer 963 may cover the surface (e.g., the entire surface) including filling up the holes 960. In some examples, the protective layer 963 includes an organic protective layer. In some examples, the protective layer 963 includes a transparent layer.

Referring to FIG. 9C, operation 905 includes applying and curing a molding 920 over the surface to fill gaps in between the modules. Operation 905 includes removing portions of the protective layer 963. Operation 905 includes performing photolithography and etch process to create an opening to the hole 960. In some examples, the protective layer 963 may remain on the sidewall of the hole 960. In some examples, operation 905 includes forming the fan-out structures by depositing PVD Ti/Al and performing a fan-Out photolithography and etch Ti/Al process to create RDL and wire bond pad. In some examples, operation 905 includes depositing SiO2. In some examples, operation 905 includes performing photolithography and etch process to create a passivation opening for the wire bond Al pad. In some examples, the layer 963 and the layer 961 may remain over the active region 958, which may assist with reducing flare.

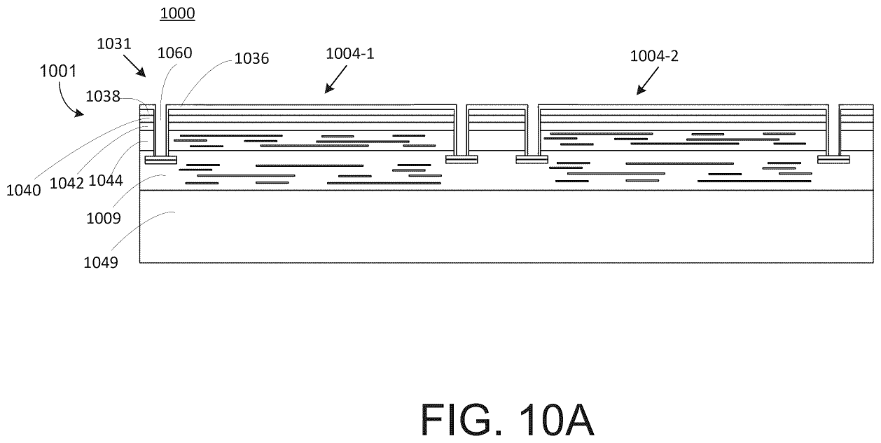

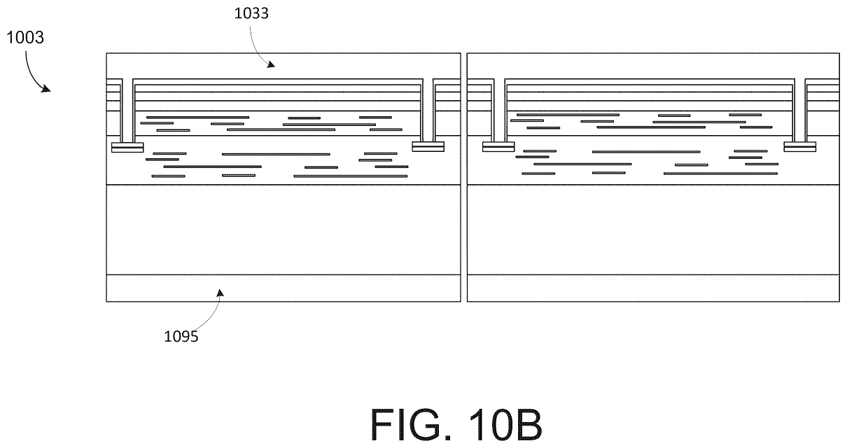

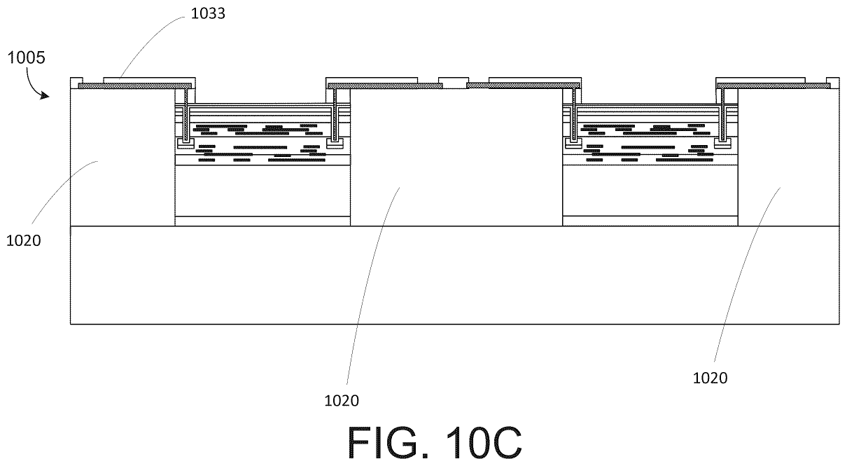

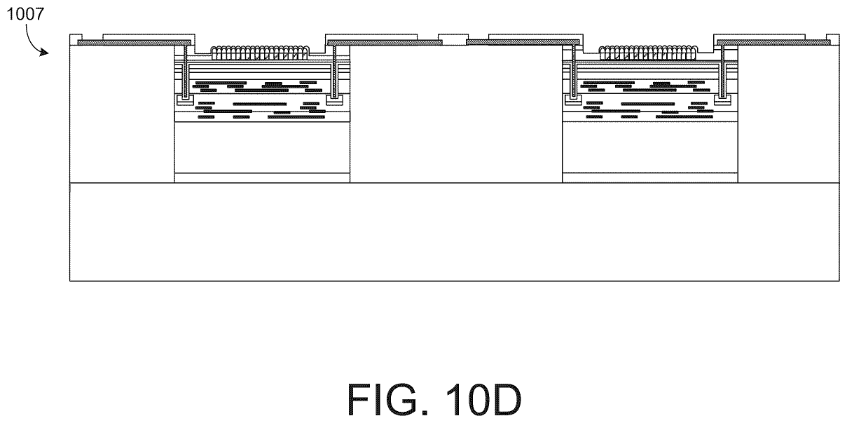

FIGS. 10A to 10D illustrate a process 1000 for generating a sensor module according to an aspect. In some examples, the process 1000 of FIGS. 10A to 10D depicts example operations of generating the sensor module 504 of FIG. 5. However, the process 1000 of FIGS. 10A to 10D may be applicable to other implementations discussed herein.

Referring to FIG. 10A, operation 1001 includes receiving a sensor substrate assembly 1031. The sensor substrate assembly 1031 may include multiple sensor modules such as a sensor module 1004-1 and a sensor module 1004-2. The sensor substrate assembly 1031 includes a layer 1036, a layer 1038, a passivation layer 1040, a sensor layer 1042 (e.g., epitaxial silicon layer), a sensor layer 1044 with metallic traces, an integrated circuit layer 1009 with metallic traces, and a layer 1049.

Referring to FIG. 10B, operation 1003 includes applying a protective layer 1033 (e.g., a spin-coat organic protective layer). In some examples, the protective layer 1033 is applied over the surface (e.g., the entire surface) including filling up the holes 1060. This layer may stay on the sidewall of the holes 1060 and may be removed from the array later in the process. Operation 1003 may include applying an attachment layer 1095 to the layer 1049.

Referring to FIG. 10C, operation 1005 includes applying a molding 1020 over the surface (e.g., the entire surface) to fill gaps in between the die and curing the molding 1020. Operation 1005 may include removing portions of the protective layer 1033. Operation 1005 may include performing photolithography and etch process to create an opening to the hole. In some examples, protective layer 1033 stays on the sidewall of the hole. Operation 1005 may include depositing a metal material (e.g., PVD Ti/Al), performing a fan-out photolithography and etch process (e.g., etch Ti/Al) to create a redistribution layer (e.g., RDL) and wire bond pad, and depositing silicon dioxide (e.g., SiO2). In some examples, operation 1005 includes performing a photolithography and etch process to create a passivation opening for the wire bond pad (e.g., aluminum wire bond pad). Operation 1005 may include performing a photolithography and etch process to remove organic passivation from the active array. Referring to FIG. 10D, operation 1007 includes performing a fill process for the hole, photo of color and black periphery materials (e.g., RGB), performing photo and etch, depositing silicon dioxide (e.g., SiO2), and performing photo/etch.

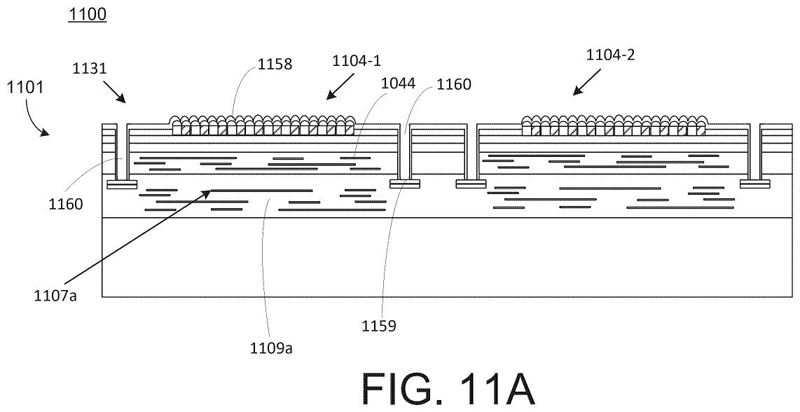

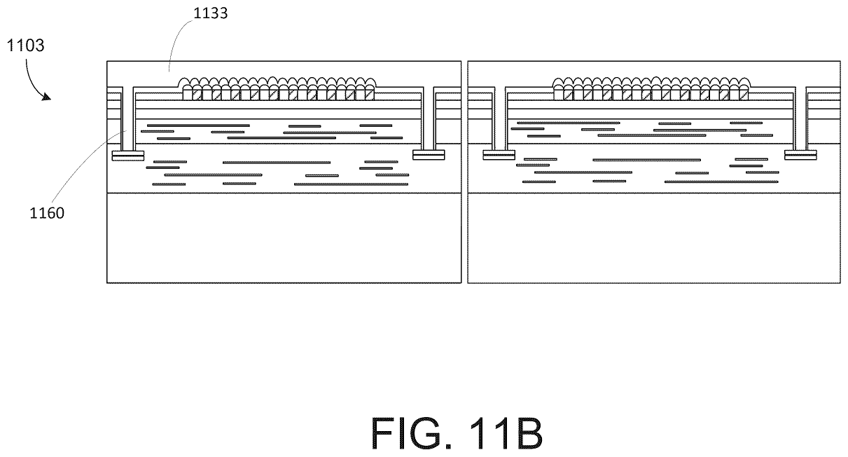

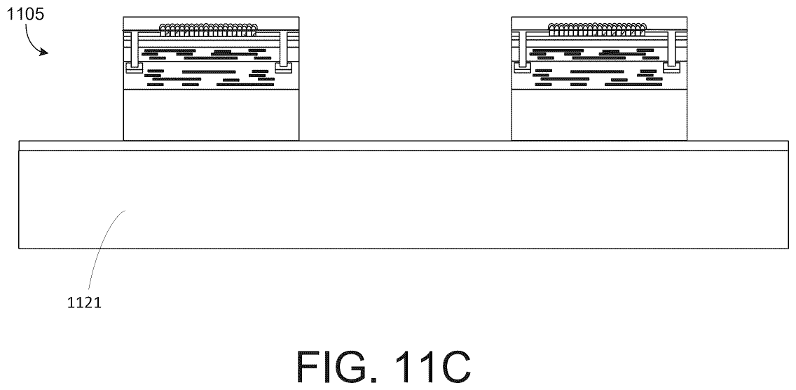

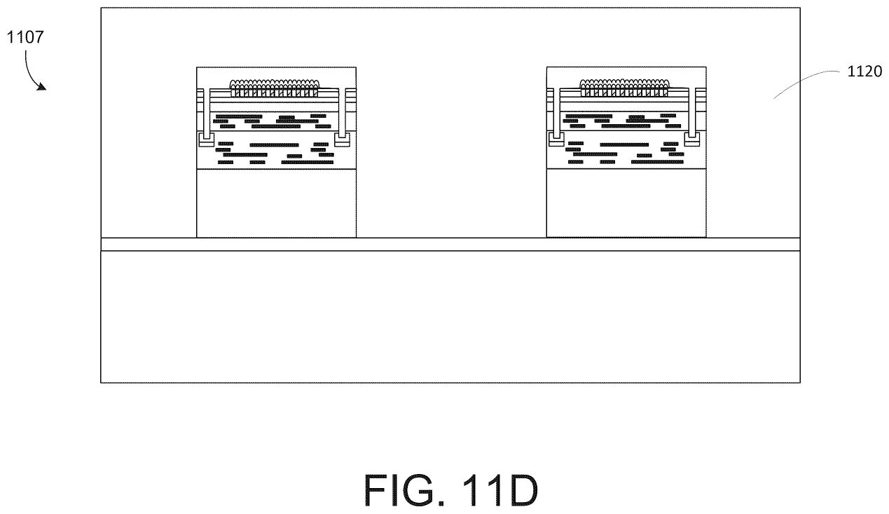

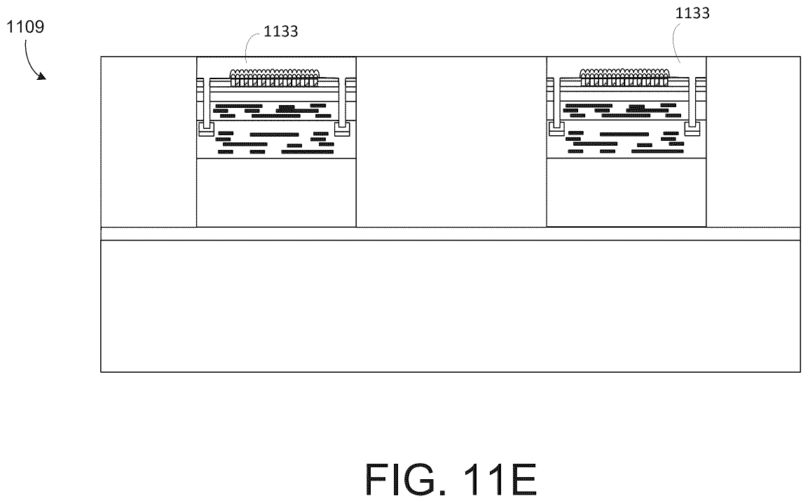

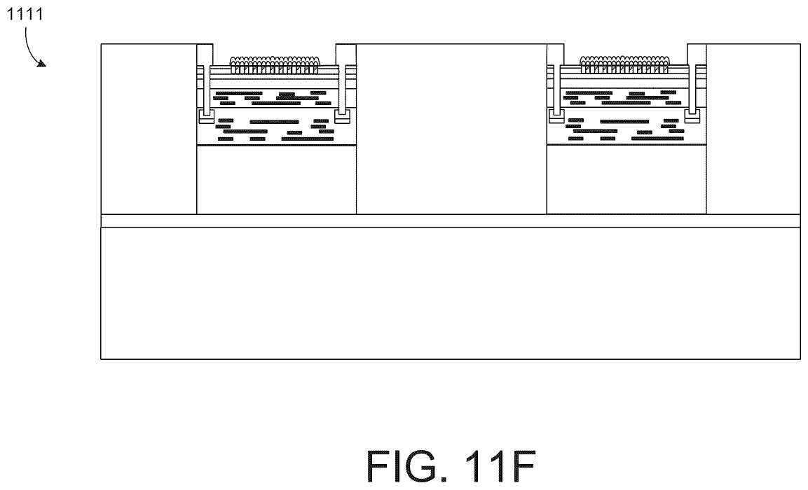

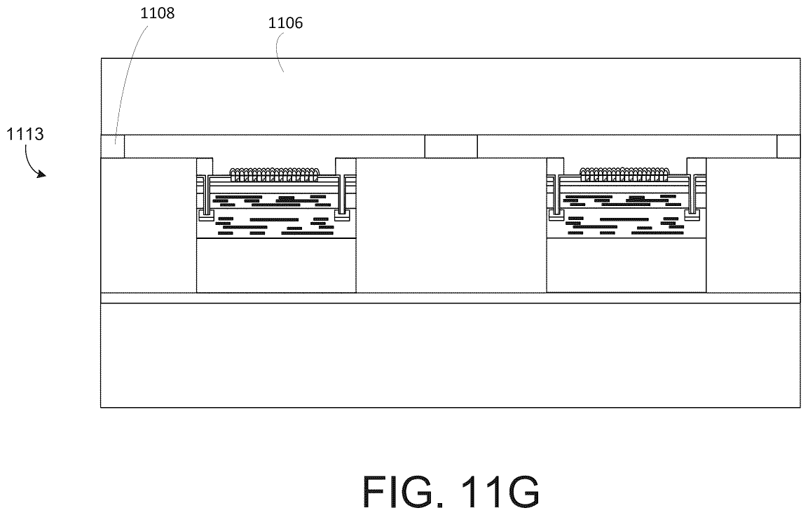

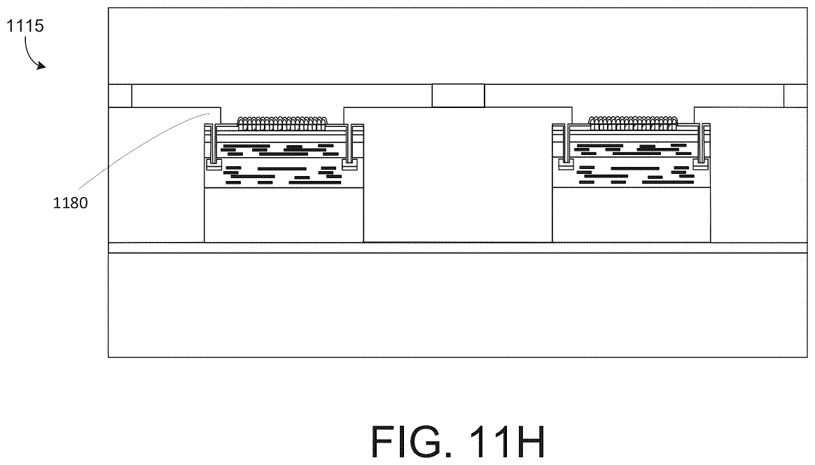

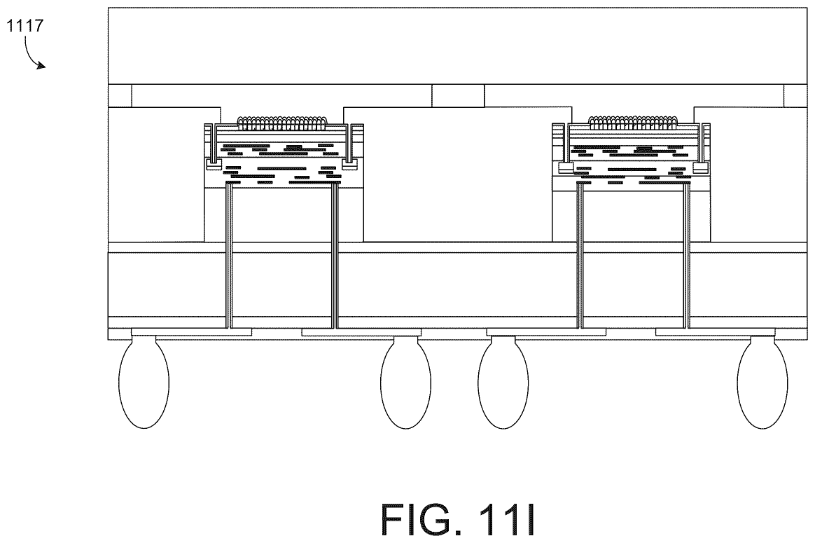

FIGS. 11A to 11I illustrate a process 1100 for constructing a sensor package according to an aspect. In some examples, the process 1100 is used to construct the sensor package 600 of FIGS. 6A and 6B. In some examples, the sensor package 600 includes a ball-grid array structure.

Referring to FIG. 11A, operation 1101 includes receiving a sensor substrate assembly 1131. The sensor substrate assembly 1131 may include multiple sensor modules such as a sensor module 1104-1 and a sensor module 1104-2.

The sensor substrate assembly 1131 includes a plurality of layers such as protective layer(s), passivation layer(s), sensor layer(s), a sensor layer with metallic traces, an integrated circuit layer with metallic traces, and a bottom layer. For each sensor module, the sensor substrate assembly 1131 includes an active region 1158 and holes 1160 (e.g., two holes). Each sensor module includes an application-specific integrated circuit 1107a that is embedded into a structure of a respective sensor module. The application-specific integrated circuit includes an integrated circuit layer 1109a that is disposed below the sensor layer. The integrated circuit layer includes a contact terminal 1159, which is exposed by a hole 1160.

Referring to FIG. 11B, operation 1103 includes applying a spin-coat organic protective layer 1133 over the surface (e.g., the entire surface) including filling up the holes 1160. This layer may stay on the sidewall of the holes 1160 and may be removed from the array later in the process. In some examples, a silicon nitride stop layer may be deposited at this stage. Operation 1103 may include thin ASIC down (e.g., <50 um) and CMP.

Referring to FIG. 11C, operation 1105 includes creating alignment marks on permanent Si carrier wafer 1121, align and pick and place (PnP) stack die on the carrier wafer 1121, bond with an adhesive (e.g., fusion SiO2/SiO2 bond), and native SiO2 on the ASIC backside.

Referring to FIG. 11D, operation 1107 includes applying molding 1120 over the surface (e.g., the entire surface) to fill gaps in between the die (e.g., sensor modules). Referring to FIG. 11E, operation 1109 includes CMP down to the organic protective layer 1133. Referring to FIG. 11F, operation 1111 includes photolithography and etch to remove organic passivation (e.g., all organic passivation from the active array). Referring to FIG. 11G, operation 1113 includes glass attach (e.g., attaching radiation transmitting substrate 1106) with glass attach adhesive (e.g., material 1108, also referred to as a dam member) on the mold area. Referring to FIG. 11H, operation 1115 includes an alternate process for operation 1113. Operation 1115 includes applying mold material 1180 inside the hole and on the surface. The mold material 1180 may be light absorbing material with minimal reflection. Referring to FIG. 11I, operation 1117 includes thin carrier, form TSV/RDL (e.g., passivation, TSV, sidewall protection, Ti/Al metallization, solder bump (or sintering bump) and reflow).

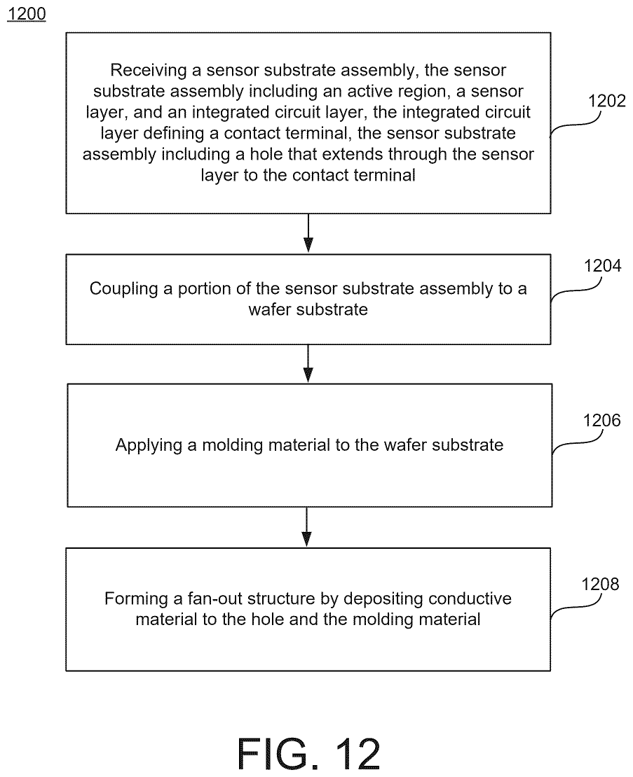

FIG. 12 depicts a flowchart 1200 depicting a method with example operations for manufacturing a sensor module with an application-specific integrated circuit and a fan-out structure according to an aspect. The flowchart may be applicable to any of the sensor modules discussed herein. Although the flowchart 1200 of FIG. 12 illustrates operations in sequential order, it will be appreciated that this is merely an example, and that additional or alternative operations may be included. Further, operations of FIG. 12 and related operations may be executed in a different order than that shown, or in a parallel or overlapping fashion.

Operation 1202 includes receiving a sensor substrate assembly, the sensor substrate assembly including an active region, a sensor layer, and an integrated circuit layer, the integrated circuit layer defining a contact terminal, the sensor substrate assembly including a hole that extends through the sensor layer to the contact terminal. Operation 1204 includes coupling a portion of the sensor substrate assembly to a wafer substrate. Operation 1206 includes applying a molding material to the wafer substrate. Operation 1208 includes forming a fan-out structure by depositing conductive material to the hole and the molding material.

Clause 1. A sensor package comprising: a radiation transmitting substrate; and a sensor module coupled to the radiation transmitting substrate via a material that positions the radiation transmitting substrate away from an active region of the radiation transmitting substrate, the sensor module including an integrated circuit embedded into the sensor module, the sensor module including a fan-out structure including a first end portion and a second end portion, the first end portion being coupled to the integrated circuit, the second end portion being coupled to a conductive component; and a substrate coupled to the sensor module.

Clause 2. The sensor package of clause 1, wherein the conductive component is a bond wire, a portion of the bond wire being encapsulated by the adhesive material.

Clause 3. The sensor package of clause 2, wherein the portion of the bond wire is a first portion, the sensor package further comprising: an encapsulation material that encapsulates a second portion of the bond wire.

Clause 4. The sensor package of clause 1, wherein the conductive component is a conductive ball member.

Clause 5. The sensor package of clause 1, wherein the sensor module includes a sensor layer and an integrated circuit layer, the fan-out structure including a conductive portion that extends through a hole in the sensor layer in a first direction.

Clause 6. The sensor package of clause 5, wherein the conductive portion is a first conductive portion, the sensor module including a molding portion, the fan-out structure including a second conductive portion that extends on the molding portion in a second direction, the second end portion being defined by a portion of the second conductive portion.

Clause 7. The sensor package of clause 1, wherein the sensor module includes a sensor layer, an integrated circuit layer, and a wafer substrate, the fan-out structure including a conductive portion that extends through a hole in the wafer substrate in a first direction.

Clause 8. The sensor package of clause 7, wherein the conductive portion is a first conductive portion, the fan-out structure including a second conductive portion that extends on a surface of the wafer substrate in a second direction, the second end portion being defined by a portion of the second conductive portion.

Clause 9. A sensor module comprising: an active region; a sensor layer; an integrated circuit layer; and a fan-out structure including a first end portion and a second end portion, the first end portion being coupled to a contact terminal defined by the integrated circuit layer, the second end portion configured to be coupled to a conductive component.

Clause 10. The sensor module of clause 9, wherein the fan-out structure includes a conductive portion that extends through a hole in the sensor layer in a first direction.

Clause 11. The sensor module of clause 10, wherein the conductive portion is a first conductive portion, the sensor module including a molding portion, the fan-out structure including a second conductive portion that extends on a surface the molding portion in a second direction, the second end portion being defined by a portion of the second conductive portion.

Clause 12. The sensor module of clause 11, further comprising: a wafer substrate, the molding portion contacting a portion of the wafer substrate, the molding portion contacting an edge of the integrated circuit layer, the molding portion contacting an edge of the sensor layer.

Clause 13. The sensor module of clause 11, further comprising: a protective layer that at least partially covers the second conductive portion, the second end portion being exposed through the protective layer.

Clause 14. The sensor module of clause 9, further comprising: a protective layer that covers the active region.

Clause 15. The sensor module of clause 9, further comprising: a wafer substrate, the fan-out structure including a conductive portion that extends through a hole in the wafer substrate in a first direction.

Clause 16. The sensor module of clause 15, wherein the conductive portion is a first conductive portion, the fan-out structure including a second conductive portion that extends on a surface of the wafer substrate in a second direction, the second end portion being defined by a portion of the second conductive portion.

Clause 17. The sensor module of clause 9, wherein the conductive component is a conductive ball member.

Clause 18. The sensor module of clause 9, wherein the conductive component is a bond wire.

Clause 19. A method for manufacturing a sensor module, the method comprising: receiving a sensor substrate assembly, the sensor substrate assembly including an active region, a sensor layer, and an integrated circuit layer, the integrated circuit layer defining a contact terminal, the sensor substrate assembly including a hole that extends through the sensor layer to the contact terminal; coupling a portion of the sensor substrate assembly to a wafer substrate; applying a molding material to the wafer substrate; and forming a fan-out structure by depositing conductive material to the hole and the molding material.

Clause 20. The method of clause 19, further comprising: applying passivation material to the active region and the hole;

It will be understood that, in the foregoing description, when an element is referred to as being connected to, electrically connected to, coupled to, or electrically coupled to another element, it may be directly connected or coupled to the other element, or one or more intervening elements may be present. In contrast, when an element is referred to as being directly connected to or directly coupled to another element, there are no intervening elements. Although the terms directly connected to, or directly coupled to may not be used throughout the detailed description, elements that are shown as being directly connected or directly coupled can be referred to as such. The claims of the application, if any, may be amended to recite exemplary relationships described in the specification or shown in the figures. Implementations of the various techniques described herein may be implemented in (e.g., included in) digital electronic circuitry, or in computer hardware, firmware, software, or in combinations of them. Portions of methods also may be performed by, and an apparatus may be implemented as, special purpose logic circuitry, e.g., an FPGA (field programmable gate array) or an ASIC (application specific integrated circuit).

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments. It should be understood that they have been presented by way of example only, not limitation, and various changes in form and details may be made. Any portion of the apparatus and/or methods described herein may be combined in any combination, except mutually exclusive combinations. The embodiments described herein can include various combinations and/or sub-combinations of the functions, components and/or features of the different embodiments described.

What is claimed is:

1. A sensor package comprising:
a radiation transmitting substrate; and
a sensor module coupled to the radiation transmitting substrate via a material that positions the radiation transmitting substrate away from an active region of the radiation transmitting substrate, the sensor module including an integrated circuit embedded into the sensor module,
the sensor module including a fan-out structure including a first end portion and a second end portion, the first end portion being coupled to the integrated circuit, the second end portion being coupled to a conductive component; and
a substrate coupled to the sensor module.

2. The sensor package of claim 1, wherein the conductive component is a bond wire, a portion of the bond wire being encapsulated by the material.

3. The sensor package of claim 2, wherein the portion of the bond wire is a first portion, the sensor package further comprising:
an encapsulation material that encapsulates a second portion of the bond wire.

4. The sensor package of claim 1, wherein the conductive component is a conductive ball member.

5. The sensor package of claim 1, wherein the sensor module includes a sensor layer and an integrated circuit layer, the fan-out structure including a conductive portion that extends through a hole in the sensor layer in a first direction.

6. The sensor package of claim 5, wherein the conductive portion is a first conductive portion, the sensor module including a molding portion, the fan-out structure including a second conductive portion that extends on the molding portion in a second direction, the second end portion being defined by a portion of the second conductive portion.

7. The sensor package of claim 1, wherein the sensor module includes a sensor layer, an integrated circuit layer, and a wafer substrate, the fan-out structure including a conductive portion that extends through a hole in the wafer substrate in a first direction.

8. The sensor package of claim 7, wherein the conductive portion is a first conductive portion, the fan-out structure including a second conductive portion that extends on a surface of the wafer substrate in a second direction, the second end portion being defined by a portion of the second conductive portion.

9. A sensor module comprising:
an active region;
a sensor layer;
an integrated circuit layer; and
a fan-out structure including a first end portion and a second end portion, the first end portion being coupled to a contact terminal defined by the integrated circuit layer, the second end portion configured to be coupled to a conductive component.

10. The sensor module of claim 9, wherein the fan-out structure includes a conductive portion that extends through a hole in the sensor layer in a first direction.

11. The sensor module of claim 10, wherein the conductive portion is a first conductive portion, the sensor module including a molding portion, the fan-out structure including a second conductive portion that extends on a surface the molding portion in a second direction, the second end portion being defined by a portion of the second conductive portion.

12. The sensor module of claim 11, further comprising:
a wafer substrate, the molding portion contacting a portion of the wafer substrate, the molding portion contacting an edge of the integrated circuit layer, the molding portion contacting an edge of the sensor layer.

13. The sensor module of claim 11, further comprising:
a protective layer that at least partially covers the second conductive portion, the second end portion being exposed through the protective layer.

14. The sensor module of claim 9, further comprising:
a protective layer that covers the active region.

15. The sensor module of claim 9, further comprising:
a wafer substrate, the fan-out structure including a conductive portion that extends through a hole in the wafer substrate in a first direction.

16. The sensor module of claim 15, wherein the conductive portion is a first conductive portion, the fan-out structure including a second conductive portion that extends on a surface of the wafer substrate in a second direction, the second end portion being defined by a portion of the second conductive portion.

17. The sensor module of claim 9, wherein the conductive component is a conductive ball member.

18. The sensor module of claim 9, wherein the conductive component is a bond wire.

19. A method for manufacturing a sensor module, the method comprising:
receiving a sensor substrate assembly, the sensor substrate assembly including an active region, a sensor layer, and an integrated circuit layer, the integrated circuit layer defining a contact terminal, the sensor substrate assembly including a hole that extends through the sensor layer to the contact terminal;
coupling a portion of the sensor substrate assembly to a wafer substrate;
applying a molding material to the wafer substrate; and
forming a fan-out structure by depositing conductive material in the hole and the molding material.

20. The method of claim 19. further comprising:
applying passivation material to the active region and the hole.
